(19) United States
(12) Patent Application Publication
(10) Pub. No.: US 2024/0309249 A1
(43) Pub. Date: Sep. 19, 2024

(54) Acrylate Adhesive for Contact With Liquid Coolant

(71) Applicant: Zephyros, Inc., Romeo, MI (US)

(72) Inventors: Nathalie Parent, Molsheim Cedex (FR); Peter Cate, Gloucestershire (GB)

(21) Appl. No.: 18/578,353

(22) PCT Filed: Jul. 19, 2022
(86) PCT No.: PCT/EP2022/070168

§ 371 Date: Jan. 11, 2024

(30) Foreign Application Priority Data
Jul. 19, 2021 (EP) 21186449.1

(51) Int. Cl. C09J 133/10; C09J 11/06

(52) U.S. Cl. CPC C09J 133/10; C09J 11/06

(57) ABSTRACT

The invention relates to the use of a curable adhesive comprising (i) a (meth)acrylic acid, (ii) a C₁₋₆-alkyl (meth)acry late. (iii) optionally, a hydroxy-C₁₋₆-alkyl (meth)acrylate, (iv) optionally, a cycloalkyl (meth)acrylate; (v) optionally, one or more additional ethylenically unsaturated monomers, and (vi) a polymerization initiator: for adhesively bonding a first substrate and a second substrate, preferably forming a battery cooling plate or a cooling plate for an electronic component, via the cured adhesive thereby obtaining between the first substrate and the second substrate a conduit for a liquid coolant to flow through and to come into direct contact with the cured adhesive.

Priority is claimed of European patent application no. 21 186 449.1 that was filed on Jul. 19, 2021.

The invention relates to the use of a curable adhesive comprising (i) a (meth)acrylic acid, (ii) a C₁₋₆-alkyl (meth)acrylate, (iii) optionally, a hydroxy-C₁₋₆-alkyl (meth)acrylate, (iv) optionally, a cycloalkyl (meth)acrylate; (v) optionally, one or more additional ethylenically unsaturated monomers, and (vi) a polymerization initiator; for adhesively bonding a first substrate and a second substrate, preferably forming a battery cooling plate or a cooling plate for an electronic component, via the cured adhesive thereby obtaining between the first substrate and the second substrate a conduit for a liquid coolant to flow through and to come into direct contact with the cured adhesive.

Electrical systems within vehicles, such as hybrid, electric, and fuel cell vehicles, have advanced in complexity and power usage, relying in part on large batteries to store energy. Energy flowing into the battery or being discharged from the battery to power the vehicle and its accessories causes heating in the battery cells, where the higher the current flow, the greater the heating effect. Unfortunately, the increased heat in the battery assembly can disadvantageously impact its performance. Cooling systems are therefore provided in battery packs to maintain a particular operating temperature or temperature range of the battery.

US 2020/0227794 A1 relates to a battery cooling plate that comprises a first substrate and a second substrate; wherein the first substrate and the second substrate are adhesively bonded via an adhesive layer; wherein a conduit is formed between the first substrate and the second substrate having an inlet and an outlet that forms a flow field for a coolant to flow through; wherein the adhesion layer forms a tight fluid seal to prevent leakage of the coolant from the conduit to a bonded region proximal to the conduit area between the first substrate and the second substrate. The adhesive layer comprises an adhesive, for example, comprising at least one of a silicone polymer, an epoxy, an alkyd, ethylene vinyl acetate, an acrylic polymer, a polyolefin, or a polyurethane.

However, in the course of operating cooling plates of such design, the adhesive layer is continuously exposed to a cooling liquid. The cooling liquid is circulated and guided through the conduit of the cooling plate where is takes up heat that is dissipated from the battery. The cooling liquid can warm up to temperatures of 60° C. and more. Cooling liquids typically contain a significant amount of ethylene glycol, typically mixtures of ethylene glycol with water and anti-corrosion additives, and it has been found that adhesives conventionally used for preparing the adhesive layer of cooling plates do not have a satisfactory resistance against such cooling liquids containing ethylene glycol, especially at elevated temperatures. Thus, adhesive strength deteriorates over time and in a worst case may even lead to adhesive failure. Conventional adhesives of this type that do not provide sufficient resistance against such cooling liquids are based upon e.g. epoxy resins and amines as curatives.

Materials have been developed that have a high resistance against ethylene glycol and aqueous mixtures comprising ethylene glycol.

EP 3 832 786 A1 relates to a cooling plate and a battery structure. The cooling plate includes: a resin plate in which a plurality of groove portions are formed; and a metal plate provided over a surface of the resin plate where the groove portions are formed, in which the resin plate and the metal plate are bonded to each other through an adhesive layer, and the groove portion of the resin plate forms a flow path for cooling water. In the examples of EP 3 832 786 A1, an adhesive was applied containing epoxy group-containing acrylic modified rubber as a main component, prepared according to Example 3 of Japanese Examined Patent Publication No. S60-26427.

JP 2010 184406 A relates to a hose for transporting refrigerant having refrigerant permeation resistance (refrigerant impermeability) and flexibility.

CN 102 840 328 A relates to sealing elements, in particular to a thermostat sealing element and a manufacturing method thereof. The thermostat sealing element is formed by combining a rubber body and a frame, wherein the frame is of a stepped bending structure and is coated with the rubber body outside; the rubber body is made of low-pressure-variability ethylene propylene diene monomer (EPDM). The frame is made of brass so that the sealing element has good ductility in the compression state and plays a good sealing effect; and the ethylene propylene diene monomer which has high ethylene glycol resistance is taken as the raw material, so that the requirement of the working condition of the thermostat can be better met.

US 2005 0005989 A1 relates to a tubing which includes a layer of cross-linked polyamide. The polyamide layer can include a cross-linking aid, such as triallyliscocyanurant or TAIC, to assist in cross-linking the layer. When the polyamide layer is exposed to high-level radiation, the polyamide layer cross-links to provide a layer having high temperature resistance and high glycol resistance.

US 2011 0060079 A1 relates to a polyamide resin composition comprising a resin of polyamide and polyacrylate mixed with a compatibilizer, an inorganic nucleating agent, a glass fiber, an antioxidant, an anti-hydrolysis agent and a lubricant in a predetermined ratio, which shows superior mechanical strength and heat resistance and improved glycol resistance and visibility maintenance, thus being useful, for example in an automobile coolant reservoir tank.

US 2016 0222209 A1 relates to a polyamide composition comprising polyamide, polyketone, and rubber, wherein the polyketone is present in an amount of no more than 5 wt %, based on the total weight of the polyamide composition. The polyamide composition has and exhibits improved mechanical properties and chemical resistance both to zinc salt and glycol, and thus is particularly useful in the manufacture of articles for automotive application.

US 2020 0407605 A 1 relates to an aqueous adhesive composition which comprises an admixture of: (a) a first aqueous composition comprising, (i) one or more film forming polymers, (ii) one or more lower crystallinity polynitroso compounds, (iii) one or more higher crystallinity polynitroso compounds, and (iv) one or more bismaleimide-containing monomers; and (b) a second aqueous composition comprising (i) an aqueous dispersion of at least one phenolic resin which is a condensation product of a phenol and formaldehyde, wherein the aqueous dispersion is stabilized by at least one polyacrylate; (b) one or more latices formed from one or more halogenated polyolefins; and (c) one or more metal oxides. Bonded assemblies are tested for stability by immersing the bonded assemblies in hot glycol at 100° C. for 7 days and then measuring the tensile strength of the bonded assemblies. The bonded assemblies show improved stability against hot glycol.

However, the known materials that exhibit high resistance against hot aqueous ethylene glycol are typically not provided in form of ready to use adhesives. There is a demand for adhesives such as structural adhesives that can be used in the manufacture of cooling plates, e.g. by adhesively bonding two substrates to one another, thereby obtaining between the two substrates a conduit for a liquid coolant to flow through and to come into direct contact with the cured adhesive.

WO 2020/178105 A1 relates to a two-component adhesive, wherein first component comprises at least three, preferably at least four of a (meth)acrylic acid, a C₁₋₆-alkyl (meth)acrylate, a cycloalkyl (meth)acrylate, a hydroxy-C₁₋₆-alkyl (meth)acrylate, and a glycolether (meth)acrylate. The second component comprises a peroxide polymerization initiator. Additionally, the first component and/or the second component comprises at least one, preferably at least two, more preferably at least three and most preferably all four of a first toughening agent; a second toughening agent differing from the first toughening agent; a first impact modifier; and a second impact modifier differing from the first impact modifier. Resistance against liquid coolants is not discussed.

It is an object of the invention to provide curable adhesives such as curable structural adhesives that can be advantageously used in the manufacture of elements, e.g. battery cooling plates or cooling plates for electronic components, where in the course of the intended operation the cured adhesives come into direct contact with aqueous ethylene glycol. The adhesives should provide excellent mechanical performance and should have satisfactory resistance against aqueous cooling liquids containing ethylene glycol and anti-corrosion additives. The adhesive should be curable at temperatures below 80° C., e.g. at room temperature (23° C.), i.e. should not require heating to elevated temperatures above 80° C. (e.g. in a subsequent bake process).

These objects have been achieved by the subject-matter of the patent claims.

It has been surprisingly found that curable adhesives comprising (i) a (meth)acrylic acid; (ii) a C₁₋₆-alkyl (meth)acrylate; (iii) optionally, a hydroxy-C₁₋₆-alkyl (meth)acrylate; (iv) optionally, a cycloalkyl (meth)acrylate; (v) optionally, one or more additional ethylenically unsaturated monomers; and (vi) a polymerization initiator have improved resistance against aqueous ethylene glycol, also at elevated temperatures. Therefore, these curable adhesives can be advantageously used in the manufacture of elements, such as battery cooling plates or cooling plates for electronic components, where in the course of the intended operation the cured adhesives come into direct contact with aqueous ethylene glycol.

Further, it has been surprisingly found that curable adhesives additionally comprising a filler, in particular a silicate filler, have improved resistance against humid aging, also at elevated temperatures.

A first aspect of the invention relates to the use of a curable adhesive comprising
a (meth)acrylic acid;
a C₁₋₆-alkyl (meth)acrylate;
optionally, a hydroxy-C₁₋₆-alkyl (meth)acrylate;
optionally, a cycloalkyl (meth)acrylate;
optionally, one or more additional ethylenically unsaturated monomers; and
a polymerization initiator;

for adhesively bonding a first substrate and a second substrate, preferably forming a battery cooling plate or a cooling plate for an electronic component, via the (cured) adhesive thereby obtaining between the first substrate and the second substrate a conduit for a liquid coolant to flow through and to come into direct contact with the (cured) adhesive.

The curable adhesive that is used according to the invention after curing provides a fast-curing toughened adhesives having excellent resistance against coolant liquids comprising aqueous ethylene glycol, also at elevated temperatures. The adhesive provides primerless adhesion to most metals, thermoplastics and composites.

Without wishing to be bound to any scientific theory, it seems that the curable adhesive that is used according to the invention after curing has a comparatively high crosslink density that contributes to the resistance against coolant liquids comprising e.g. aqueous ethylene glycol. A comparable cross-link density can hardly be achieved with curable adhesives that are based upon other chemistries such as epoxy, especially other two-component adhesives that after mixing of the two components with one another spontaneously cure at room temperature (23° C.) without requiring heating to elevated temperatures. Curability at room temperature is desirable because in many applications the first substrate and the second substrate are adhesively bonded to one another and thereafter in the course of manufacture not subjected to elevated temperatures for other reasons, such as in an oven for anti-corrosion e-coat curing and the like.

The curable adhesive that is used according to the invention after curing provides a cured adhesive having improved resistance against coolant liquids. Preferably, the test specimens for determining improved resistance against coolant liquids are prepared by placing the curable adhesive between two aluminum substrates, which preferably have been pretreated by means of a laser, at a gap distance of 0.3 mm and allowing the adhesive to cure at 23° C. for at least 4 days. Subsequently, the thus obtained test specimens are immersed to a simulated cooling liquid consisting of ethylene glycol and water (50/50 w/w), and after immersion the lap shear strength is measured at 23° C. according to ASTM method D1002.

When comparing the lap shear strength value measured after immersion at 90° C. for 7 days with the lap shear strength value measured prior to immersion of a specimen described above, the value has preferably relatively decreased by not more than 22%, preferably not more than 20%, more preferably not more than 18%, still more preferably not more than 16%, yet more preferably not more than 14%, even more preferably not more than 12%, most preferably not more than 10%, and in particular not more than 8.0%.

When comparing the lap shear strength value measured after immersion at 90° C. for 14 days with the lap shear strength value measured prior to immersion of a specimen described above, the value has preferably relatively decreased by not more than 24%, preferably not more than 22%, more preferably not more than 20%, still more preferably not more than 18%, yet more preferably not more than 16%, even more preferably not more than 14%, most preferably not more than 12%, and in particular not more than 10%.

When comparing the lap shear strength value measured after immersion at 70° C. for 30 days with the lap shear strength value measured prior to immersion of a specimen described above, the value has preferably relatively decreased by not more than 28%, preferably not more than 26%, more preferably not more than 24%, still more preferably not more than 22%, yet more preferably not more than 20%, even more preferably not more than 18%, most preferably not more than 16%, and in particular not more than 14%.

When comparing the lap shear strength value measured after immersion at 70° C. for 60 days with the lap shear strength value measured prior to immersion of a specimen described above, the value has preferably relatively decreased by not more than 30%, preferably not more than 35%, more preferably not more than 33%, still more preferably not more than 31%, yet more preferably not more than 29%, even more preferably not more than 27%, most preferably not more than 25%, and in particular not more than 23%.

In other preferred embodiments, the test specimens for determining improved resistance against coolant liquids are prepared by placing the curable adhesive between two aluminum substrates, which preferably have been pretreated by means of abrasion and acetone cleaning, at a gap distance of 0.3 mm and allowing the adhesive to cure at 23° C. for at least 3 days. Subsequently, the thus obtained test specimens are immersed to a simulated cooling liquid consisting of ethylene glycol and water (50/50 w/w), and after immersion the lap shear strength is measured at 23° C. according to ASTM method D1002.

When comparing the lap shear strength value measured after immersion at 90° C. for 7 days with the lap shear strength value measured prior to immersion of a specimen described above, the value has preferably relatively decreased by not more than 46%, preferably not more than 44%, more preferably not more than 42%, still more preferably not more than 40%, yet more preferably not more than 38%, even more preferably not more than 36%, most preferably not more than 34%, and in particular not more than 32%.

When comparing the lap shear strength value measured after immersion at 90° C. for 14 days with the lap shear strength value measured prior to immersion of a specimen described above, the value has preferably relatively decreased by not more than 54%, preferably not more than 52%, more preferably not more than 50%, still more preferably not more than 48%, yet more preferably not more than 46%, even more preferably not more than 44%, most preferably not more than 42%, and in particular not more than 40%.

In still other preferred embodiments, the test specimens for determining improved resistance against coolant liquids are prepared by placing the curable adhesive between two aluminum substrates, which preferably have been pretreated by means of abrasion and acetone cleaning, at a gap distance of 0.3 mm and allowing the adhesive to cure at 23° C. for at least 3 days. Subsequently, the thus obtained test specimens are immersed to humid cataplasma (100% relative humidity), and after immersion the lap shear strength is measured at 23° C. according to ASTM method D1002.

Humid cataplasma aging is preferably performed in accordance with PSA D47 1165, preferably PSA D47 1165 (H7).

When comparing the lap shear strength value measured after immersion at 70° C. for 7 days with the lap shear strength value measured prior to immersion of a specimen described above, the value has preferably relatively decreased by not more than 30%, preferably not more than 28%, more preferably not more than 26%, still more preferably not more than 24%, yet more preferably not more than 22%, even more preferably not more than 20%, most preferably not more than 18%, and in particular not more than 16%.

When comparing the lap shear strength value measured after immersion at 70° C. for 14 days with the lap shear strength value measured prior to immersion of a specimen described above, the value has preferably relatively decreased by not more than 36%, preferably not more than 34%, more preferably not more than 32%, still more preferably not more than 30%, yet more preferably not more than 28%, even more preferably not more than 26%, most preferably not more than 24%, and in particular not more than 22%.

When comparing the lap shear strength value measured after immersion at 70° C. for 21 days with the lap shear strength value measured prior to immersion of a specimen described above, the value has preferably relatively decreased by not more than 38%, preferably not more than 36%, more preferably not more than 34%, still more preferably not more than 32%, yet more preferably not more than 30%, even more preferably not more than 28%, most preferably not more than 26%, and in particular not more than 24%.

For the purpose of the specification, unless expressly stated otherwise, percentages are percent by weight. Unless expressly stated otherwise, any norms such as EN ISO, ASTM, PSA and the like are in the official version that is valid on Jul. 1, 2020. The expression “essentially consists of” means a content of at least 95 wt.-%, preferably at least 99 wt.-%, relative to the total weight of the component to which the definition refers.

In preferred embodiments, at least one of the first substrate and the second substrate comprises a metal.

In preferred embodiments, at least one of the first substrate and the second substrate comprises a polymer.

In a preferred embodiment, the first substrate and the second substrate form a battery cooling plate, e.g. a battery cooling plate for a static application or a battery cooling plate for a vehicle such as an automobile.

In another preferred embodiment, the first substrate and the second substrate form a cooling plate for an electronic component such as a processor and the like.

Preferably, the cured adhesive forms a tight seal to prevent leakage of the liquid coolant from the conduit. The design of the conduit according to the invention is not particularly limited. Preferably, the conduit comprises an inlet and an outlet connected by e.g. a serpentine path or a path of any other shape. Various designs are contemplated according to the invention, e.g. designs with turbulence inducing fins, random designs, and the like.

Preferably, the liquid coolant comprises ethylene glycol. Preferably, the liquid coolant comprises water, ethylene glycol and optionally anti-corrosion additives.

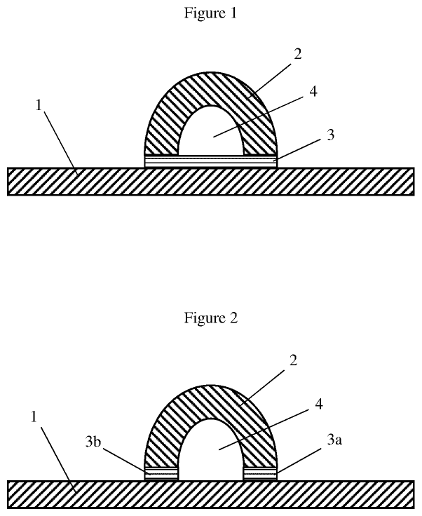

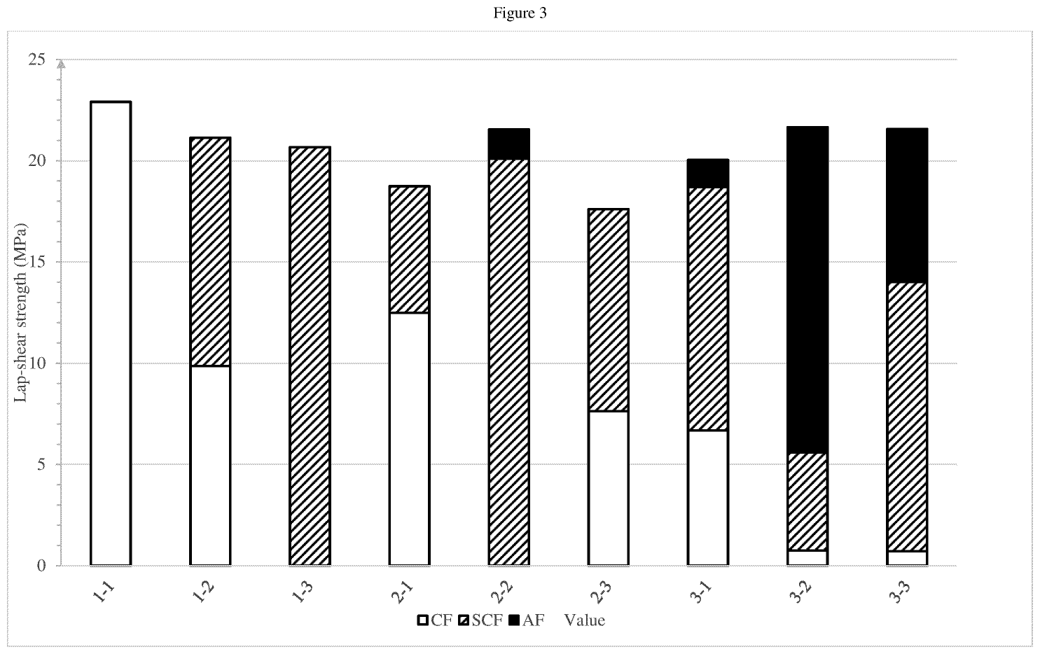

FIGS. 1 and 2 schematically illustrate preferred embodiments of using the curable adhesive according to the invention. FIG. 1 shows a first substrate (1) and a second substrate (2), which are adhesively bonded via a cured adhesive (3) thereby obtaining between the first substrate (1) and the second substrate (2) a conduit (4) for a liquid coolant to flow through and to come into direct contact with the cured adhesive (3). FIG. 2 shows an embodiment where the cured adhesive is divided into a first portion (3a) and a second portion (3b). In either case, when liquid coolant will flow through the conduit (4), it will come into direct contact with the cured adhesive (3) and (3a/b), respectively.

FIG. 3 shows experimental data where measured values for lap shear strength in MPa have been split to partial contribution according to the observed failure mode, i.e. expressed as relative lap shear per failure mode.

In preferred embodiments, the curable adhesive that is used according to the invention is a two-component adhesive that spontaneously cures at room temperature (23° C.) when the two components are mixed with one another.

In preferred embodiments, the curable adhesive that is used according to the invention is a two-component system, wherein the curable adhesive is preferably obtained by mixing a first component and a second component with one another, wherein preferably the first component comprises
the (meth)acrylic acid;
the C₁₋₆-alkyl (meth)acrylate;
the optionally present hydroxy-C₁₋₆-alkyl (meth)acrylate;
the optionally present cycloalkyl (meth)acrylate; and
the optionally present one or more additional ethylenically unsaturated monomers;
   and wherein preferably the second component comprises the polymerization initiator.

Preferred ingredients and specific compositions of the curable adhesive that is used according to the invention are described hereinafter:

Preferably, the curable adhesive according to the invention comprises at least one, preferably at least two, more preferably at least three and still more preferably at least four of
a (meth)acrylic acid, preferably methacrylic acid or acrylic acid;
a C₁₋₆-alkyl (meth)acrylate, preferably methyl (meth)acrylate or ethyl (meth)acrylate, more preferably methyl methacrylate;
a hydroxy-C₁₋₆-alkyl (meth)acrylate, preferably hydroxyethyl (meth)acrylate or hydroxypropyl (meth)acrylate;
a cycloalkyl (meth)acrylate, preferably isobornyl acrylate or isobornyl methacrylate; and
a glycolether (meth)acrylate according to general formula (I) as defined below; preferably butyldiglycol methacrylate.

In a preferred embodiment, the curable adhesive according to the invention comprises at least three monomers, namely
a (meth)acrylic acid, preferably methacrylic acid or acrylic acid;
a C₁₋₆-alkyl (meth)acrylate, preferably methyl (meth)acrylate or ethyl (meth)acrylate, more preferably methyl methacrylate; and
a hydroxy-C₁₋₆-alkyl (meth)acrylate, preferably hydroxyethyl (meth)acrylate or hydroxypropyl (meth)acrylate.

Preferably, the curable adhesive according to the invention comprises
a (meth)acrylic acid,
a C₁₋₆-alkyl (meth)acrylate,
a hydroxy-C₁₋₆-alkyl (meth)acrylate,
optionally, a cycloalkyl (meth)acrylate; and/or
optionally, a glycolether (meth)acrylate according to general formula (I) as defined below; preferably butyldiglycol methacrylate.

Preferably, the curable adhesive according to the invention comprises (A) a (meth)acrylic acid, preferably methacrylic acid or acrylic acid; (B) a C₁₋₆-alkyl (meth)acrylate, preferably methyl (meth)acrylate or ethyl (meth)acrylate, more preferably methyl methacrylate; and (C) a hydroxy-C₁₋₆-alkyl (meth)acrylate, preferably hydroxyethyl (meth)acrylate or hydroxypropyl (meth)acrylate; preferably wherein the relative weight ratio (A):(B):(C) is from about 10:1:1 to about 1:10:1 to about 1:1:10; more preferably from about 9:1:1 to about 1:9:1 to about 1:1:9; still more preferably from about 8:1:1 to about 1:8:1 to about 1:1:8.

Preferably, the curable adhesive according to the invention comprises (A) a C₁₋₆-alkyl (meth)acrylate, preferably methyl (meth)acrylate or ethyl (meth)acrylate, more preferably methyl methacrylate; (B) a hydroxy-C₁₋₆-alkyl (meth)acrylate, preferably hydroxyethyl (meth)acrylate or hydroxypropyl (meth)acrylate; and (C) a cycloalkyl (meth)acrylate, preferably isobornyl acrylate or isobornyl methacrylate; preferably wherein the relative weight ratio (A):(B):(C) is from about 10:1:1 to about 1:10:1 to about 1:1:10; more preferably from about 9:1:1 to about 1:9:1 to about 1:1:9; still more preferably from about 8:1:1 to about 1:8:1 to about 1:1:8.

Preferably, the curable adhesive according to the invention comprises at least three monomers, namely (A) a C₁₋₆-alkyl (meth)acrylate, preferably methyl (meth)acrylate or ethyl (meth)acrylate, more preferably methyl methacrylate; (B) a hydroxy-C₁₋₆-alkyl (meth)acrylate, preferably hydroxyethyl (meth)acrylate or hydroxypropyl (meth)acrylate; and (C) a glycolether (meth)acrylate according to general formula (I) as defined above; preferably butyldiglycol methacrylate; preferably wherein the relative weight ratio (A):(B):(C) is from about 10:1:1 to about 1:10:1 to about 1:1:10; more preferably from about 9:1:1 to about 1:9:1 to about 1:1:9; still more preferably from about 8:1:1 to about 1:8:1 to about 1:1:8.

In still another preferred embodiment, the curable adhesive according to the invention comprises at least four monomers, namely
a (meth)acrylic acid, preferably methacrylic acid or acrylic acid;
a C₁₋₆-alkyl (meth)acrylate, preferably methyl (meth)acrylate or ethyl (meth)acrylate, more preferably methyl methacrylate;
a hydroxy-C₁₋₆-alkyl (meth)acrylate, preferably hydroxyethyl (meth)acrylate or hydroxypropyl (meth)acrylate; and
a cycloalkyl (meth)acrylate, preferably isobornyl acrylate or isobornyl methacrylate.

In yet another preferred embodiment, the curable adhesive according to the invention comprises at least four monomers, namely
a (meth)acrylic acid, preferably methacrylic acid or acrylic acid;
a C₁₋₆-alkyl (meth)acrylate, preferably methyl (meth)acrylate or ethyl (meth)acrylate, more preferably methyl methacrylate;
a hydroxy-C₁₋₆-alkyl (meth)acrylate, preferably hydroxyethyl (meth)acrylate or hydroxypropyl (meth)acrylate; and
a glycolether (meth)acrylate according to general formula (I), preferably butyldiglycol (meth)acrylate.

In a preferred embodiment, the curable adhesive according to the invention comprises a (meth)acrylic acid, preferably methacrylic acid or acrylic acid, and a C₁₋₆-alkyl (meth)acrylate, preferably methyl (meth)acrylate or ethyl (meth)acrylate, more preferably methyl methacrylate, wherein preferably the relative weight ratio of the (meth)acrylic acid to the C₁₋₆-alkyl (meth)acrylate is within the range of 1:(10±8), more preferably 1:(10±6), still more preferably 1:(10±5), yet more preferably 1:(10±4), even more preferably 1:(10±3), most preferably 1:(10±2), and in particular 1:(10±1).

In a preferred embodiment, the curable adhesive according to the invention comprises a (meth)acrylic acid, preferably methacrylic acid or acrylic acid, and a hydroxy-C₁₋₆-alkyl (meth)acrylate, preferably hydroxyethyl (meth)acrylate or hydroxypropyl (meth)acrylate, wherein preferably the relative weight ratio of the (meth)acrylic acid to the hydroxy-C₁₋₆-alkyl (meth)acrylate is within the range of 1:(5±4.5), more preferably 1:(5±4), still more preferably 1:(5±3.5), yet more preferably 1:(5±3), even more preferably 1:(5±2.5), most preferably 1:(5±2), and in particular 1:(5±1.5).

In a preferred embodiment, the curable adhesive according to the invention comprises a (meth)acrylic acid, preferably methacrylic acid or acrylic acid, and a cycloalkyl (meth)acrylate, preferably isobornyl acrylate or isobornyl methacrylate, wherein preferably the relative weight ratio of the (meth)acrylic acid to the cycloalkyl (meth)acrylate is within the range of 7:1 to 1:7, more preferably 6:1 to 1:6, still more preferably 5:1 to 1:5, yet more preferably 4:1 to 1:4, even more preferably 3:1 to 1:3, most preferably 2:1 to 1:2, and in particular 1.5:1 to 1:1.5.

In a preferred embodiment, the curable adhesive according to the invention comprises a (meth)acrylic acid, preferably methacrylic acid or acrylic acid, and a glycolether (meth)acrylate according to general formula (I), preferably butyldiglycol (meth)acrylate, wherein preferably the relative weight ratio of the (meth)acrylic acid to the glycolether (meth)acrylate is within the range of (1.5±1.0):1, more preferably (1.5±0.9):1, still more preferably (1.5±0.8):1, yet more preferably (1.5±0.7):1, even more preferably (1.5±0.6):1, most preferably (1.5±0.5):1, and in particular (1.5±0.4):1.

In a preferred embodiment, the curable adhesive according to the invention comprises a C₁₋₆-alkyl (meth)acrylate, preferably methyl (meth)acrylate or ethyl (meth)acrylate, more preferably methyl methacrylate, and a hydroxy-C₁₋₆-alkyl (meth)acrylate, preferably hydroxyethyl (meth)acrylate or hydroxypropyl (meth)acrylate, wherein preferably the relative weight ratio of the C₁₋₆-alkyl (meth)acrylate to the hydroxy-C₁₋₆-alkyl (meth)acrylate is within the range of (2.5±2.4): 1, more preferably (2.5±2.1):1, still more preferably (2.5±1.8):1, yet more preferably (2.5±1.5):1, even more preferably (2.5±1.2):1, most preferably (2.5±0.9):1, and in particular (2.5±0.6):1.

In a preferred embodiment, the curable adhesive according to the invention is free of at least one or both of hydroxyethyl methacrylate and hydroxypropyl methacrylate.

In a preferred embodiment, the curable adhesive according to the invention comprises a C₁₋₆-alkyl (meth)acrylate, preferably methyl (meth)acrylate or ethyl (meth)acrylate, more preferably methyl methacrylate, and a cycloalkyl (meth)acrylate, preferably isobornyl acrylate or isobornyl methacrylate, wherein preferably the relative weight ratio of the C₁₋₆-alkyl (meth)acrylate to the cycloalkyl (meth)acrylate is within the range of (8±7):1, more preferably (8±6):1, still more preferably (8±5):1, yet more preferably (8±4): 1, even more preferably (8±3):1, most preferably (8±2):1, and in particular (8±0.5):1.

In a preferred embodiment, the curable adhesive according to the invention comprises a C₁₋₆-alkyl (meth)acrylate, preferably methyl (meth)acrylate or ethyl (meth)acrylate, more preferably methyl methacrylate, and a glycolether (meth)acrylate according to general formula (I), preferably butyldiglycol (meth)acrylate, wherein preferably the relative weight ratio of the C₁₋₆-alkyl (meth)acrylate to the glycolether (meth)acrylate is within the range of (10±9):1, more preferably (10±8):1, still more preferably (10±7):1, yet more preferably (10±6):1, even more preferably (10±5):1, most preferably (10±4):1, and in particular (10±3):1.

In a preferred embodiment, the curable adhesive according to the invention comprises a hydroxy-C₁₋₆-alkyl (meth)acrylate, preferably hydroxyethyl (meth)acrylate or hydroxypropyl (meth)acrylate, and a cycloalkyl (meth)acrylate, preferably isobornyl acrylate or isobornyl methacrylate, wherein preferably the relative weight ratio of the hydroxy-C₁₋₆-alkyl (meth)acrylate to the cycloalkyl (meth)acrylate is within the range of (3±2.8):1, more preferably (3±2.4):1, still more preferably (3±2.0):1, yet more preferably (3±1.6):1, even more preferably (3±1.2):1, most preferably (3±0.8):1, and in particular (3±0.4):1.

In a preferred embodiment, the curable adhesive according to the invention comprises a hydroxy-C₁₋₆-alkyl (meth)acrylate, preferably hydroxyethyl (meth)acrylate or hydroxypropyl (meth)acrylate, and a glycolether (meth)acrylate according to general formula (I), preferably butyldiglycol (meth)acrylate, wherein preferably the relative weight ratio of the hydroxy-C₁₋₆-alkyl (meth)acrylate to the glycolether (meth)acrylate is within the range of (2.0±1.8):1, more preferably (2.0±1.6):1, still more preferably (2.0±1.4):1, yet more preferably (2.0±1.2):1, even more preferably (2.0±1.0):1, most preferably (2.0±0.8):1, and in particular (2.0±0.6):1.

In preferred embodiments, the curable adhesive according to the invention comprises at least one, preferably at least two, more preferably at least three and most preferably all four of a first toughening agent; a second toughening agent differing from the first toughening agent; a first impact modifier; and a second impact modifier differing from the first impact modifier.

In preferred embodiments, the curable adhesive according to the invention comprises a first toughening agent; or a first impact modifier.

In preferred embodiments, the curable adhesive according to the invention comprises a first toughening agent and a second toughening agent differing from the first toughening agent; or a first toughening agent and a first impact modifier; or a first impact modifier and a second impact modifier differing from the first impact modifier.

In preferred embodiments, the curable adhesive according to the invention comprises a first toughening agent and a second toughening agent differing from the first toughening agent and a first impact modifier; or a first toughening agent and a first impact modifier and a second impact modifier differing from the first impact modifier.

In a particularly preferred embodiment, the curable adhesive according to the invention comprises a first toughening agent and a second toughening agent differing from the first toughening agent and a first impact modifier and a second impact modifier differing from the first impact modifier.

The curable adhesive according to the invention is preferably a two-component system comprising a first component and a second component. While it is principally possible that the two-component component system comprises further components in addition to the first and second component, preferably the two-component system essentially consists of the first component and the second component.

In its non-activated state, the first component and the second component are then spatially separated from one another. In this non-activated state the two-component system may be stored typically having a shelf-life of at least several months. For example, the two-component system may be made commercially available in a cartridge comprising two separate chambers where the first component is contained in a first chamber of the cartridge and the second component is contained in a second chamber of the cartridge.

In its activated state, the first component and the second component are mixed with one another thereby inducing chemical reaction that finally results in formation of a cured adhesive. For example, when being contained in spatially separated chambers of a cartridge, the first component may be mixed with the second component when exiting the cartridge e.g. through a nozzle or die for application to a substrate. As the first component and the second component are mixed with one another, the ingredients thereof can chemically react with one another.

As chemical reaction takes some time that highly depends upon the ingredients of the curable adhesive, it is typically distinguished between open time and curing time. The open time is usually regarded as the time window immediately after mixing during which the curable adhesive may be applied to a substrate, flow and may still be deformed. Open time may be regarded as a lag time before chemical reaction has started or at least has proceeded to a certain extent at which applying and processing the curable adhesive becomes difficult because of advancing polymerization and curing. The curing time is usually regarded as the time window following the open time until the curable adhesive has completely reacted, i.e. until polymerization and curing reactions have been completed so that the initially curable adhesive has become a cured adhesive. The open time and the curing time may independently of one another last from a few minutes to several hours and there is no clear-cut between open time and curing time; transition may be smooth.

For certain industrial applications it can be desirable to specifically adjust open time and curing time. In certain embodiments it can be desirable to have an open time within the range of from 1 to 10 minutes and subsequently to have a curing time that is e.g. about 10 minutes. A skilled person knows that curing time is dependent on geometry of the substrates to be adhesively bonded to one another, but also on atmospheric conditions and temperature. The curing of acrylic monomers typically proceeds faster at higher temperatures. When using the curable adhesive e.g. on an assembly line, this will provide sufficient time for applying the curable adhesive to the desired substrate, but also will allow for further processing after a short period or even immediately thereafter, as polymerization and curing proceeds quickly. Thus, polymerization and curing will not significantly delay operation on the assembly line.

Preferably, the curable adhesive according to the invention is a curable structural adhesive. For the purpose of the specification, a structural adhesive is to be regarded as an adhesive that can be used to produce a load-bearing joint. Preferably, a structural adhesive is useful for engineering applications where joints typically have lap shear strengths of at least 1 MPa and, more normally, at least 10 MPa. Structural adhesives are used extensively in automotive and aircraft industry for bonding metal-to-metal, metal-to-composite and composite-to-composite parts.

A skilled person recognizes that in its spatially separated state, certain ingredients of the curable adhesive can be present in either component without inducing premature chemical reaction. Thus, unless these components comprise reactive functional groups, it makes no big difference whether these ingredients are contained in the first component or in the second component or in both the first and the second component. This is particularly the case for the optionally present first toughening agent, the second toughening agent, the first impact modifier, and the second impact modifier.

However, the radically polymerizable monomers of the curable adhesive on the one hand and the radical polymerization initiator of the curable adhesive on the other hand should be stored separate of one another. For that reason, the first component of the two-component system comprises the monomers such as (meth)acrylic acid, C₁₋₆-alkyl (meth)acrylate, hydroxy-C₁₋₆-alkyl (meth)acrylate and the optionally present one or more ethylenically unsaturated monomers; whereas the second component comprises the polymerization initiator.

Unless expressly stated otherwise, all percentages are weight percentages and are relative to the total weight of the curable adhesive, i.e. when the curable adhesive is based upon a two-component system, the overall weight of the first and second component.

Unless expressly stated otherwise, all standard test methods such as ASTM refer to the most recent edition that is valid on Jan. 1, 2019.

Unless expressly stated otherwise, “(meth)” within chemical nomenclature of acrylic acid and acrylic acid derivatives such as acrylic acid esters (i.e. acrylates) means either absence or presence of “meth”, i.e. either acrylic acid and the corresponding derivatives of acrylic acid, or methacrylic acid and the corresponding derivatives of methacrylic acid. In other words, e.g. “(meth)acrylic acid” means “acrylic acid or methacrylic acid”, and likewise “methyl (meth)acrylate” means “methyl acrylate or methyl methacrylate” (i.e. acrylic acid methyl ester or methacrylic acid methyl ester).

The curable adhesive according to the invention preferably comprises (meth)acrylic acid, preferably methacrylic acid or acrylic acid.

It has been found that (meth)acrylic acid, preferably methacrylic acid or acrylic acid, may inter alia act as adhesion promoter. Further, when the curable adhesive comprises other ingredients that are capable of reacting with carboxylic functional groups, such as free epoxy functional groups of epoxy resins, the resultant crosslinks may further improve the properties of the adhesive.

In a preferred embodiment, the curable adhesive according to the invention comprises methacrylic acid but no acrylic acid. In another preferred embodiment, the curable adhesive according to the invention comprises acrylic acid but no methacrylic acid.

Preferably, the content of the (meth)acrylic acid, preferably methacrylic acid or acrylic acid, is within the range of 5.0±4.5 wt.-%, more preferably 5.0±4.0 wt.-%, still more preferably 5.0±3.5 wt.-%, yet more preferably 5.0±3.0 wt.-%, even more preferably 5.0±2.5 wt.-%, most preferably 5.0±2.0 wt .-%, and in particular 5.0±1.5 wt.-%, in each case relative to the total weight of the curable adhesive. When the curable adhesive comprises more than a single (meth)acrylic acid, i.e. a combination a acrylic acid and methacrylic acid, the specified content of (meth)acrylic acid refers to the overall content of all (meth)acrylic acids that are contained in the curable adhesive.

Optionally, besides the (meth)acrylic acid, one or more other organic acids, such as carboxylic acids, may be employed in the adhesive formulation to enhance adhesion of the adhesive to the substrates or components. Exemplary carboxylic acids include maleic acid, acrylic acid, crotonic acid, fumaric acid, malonic acid, and the like. Additional examples of these organic or carboxylic acids are acetylene dicarboxylic acid, dibromo maleic citranoic acid, mesaconic acid, and oxalic acid.

By adding (meth)acrylic acid and optionally one or more of the above carboxylic acids, particularly strong organic carboxylic acids, the bonding characteristics of the adhesive to the subsequently bonded structural components and parts are improved. It is believed that the addition of carboxylic acids promotes adhesion to solvent-resistant and/or heat-resistant plastics, thermosets, thermoplastics, resin/glass composites, resins, fiber reinforced composites, metals, and so on, due to interactions at the molecular level, e.g., through hydrogen bonding, and the like. The addition of water to compositions comprising these acids can increase their effectiveness. These adhesive effects can further be enhanced by heat treatment of the bonds either during or after the bonding step (or both).

The curable adhesive according to the invention preferably comprises a C₁₋₆-alkyl (meth)acrylate, which is preferably selected from the group consisting of methyl acrylate, methyl methacrylate, ethyl acrylate, ethyl methacrylate, propyl acrylate, propyl methacrylate, butyl acrylate and butyl methacrylate; preferably methyl (meth)acrylate or ethyl (meth)acrylate, more preferably methyl methacrylate.

It has been found that the C₁₋₆-alkyl (meth)acrylate, preferably methyl (meth)acrylate or ethyl (meth)acrylate, more preferably methyl methacrylate, may inter alia improve the adhesion of the adhesive of plastic substrates. This is therefore particularly advantageous when the adhesive is used for bonding metal-to-composite parts or composite-to-composite parts.

Preferably, the curable adhesive comprises essentially no C₁₋₆-alkyl (meth)acrylate other than methyl methacrylate.

Preferably, the content of the C₁₋₆-alkyl (meth)acrylate, preferably methyl (meth)acrylate or ethyl (meth)acrylate, more preferably methyl methacrylate, is at most 60 wt.-%, more preferably at most 55 wt.-%, still more preferably at most 50 wt.-%, yet more preferably at most 45 wt.-%, even more preferably at most 40 wt.-%, most preferably at most 35 wt.-%, and in particular at most 30 wt.-%, in each case relative to the total weight of the curable adhesive.

Preferably, the content of the C₁₋₆-alkyl (meth)acrylate, preferably methyl (meth)acrylate or ethyl (meth)acrylate, more preferably methyl methacrylate, is within the range of 25±10 wt.-%, more preferably 25±9.0 wt.-%, still more preferably 25±8.0 wt.-%, yet more preferably 25±7.0 wt.-%, even more preferably 25±6.0 wt.-%, most preferably 25±5.0 wt.-%, and in particular 25±4.0 wt.-%, in each case relative to the total weight of the curable adhesive. When the curable adhesive comprises more than a single C₁₋₆-alkyl (meth)acrylate, the specified content of C₁₋₆-alkyl (meth)acrylate refers to the overall content of all C₁₋₆-alkyl (meth)acrylates that are contained in the curable adhesive.

The curable adhesive according to the invention preferably comprises a cycloalkyl (meth)acrylate, which is preferably selected from the group consisting of isobornyl acrylate, isobornyl methacrylate, 1-adamantyl acrylate, 1-adamantyl methacrylate, cyclohexyl acrylate, cyclohexyl methacrylate, methylcyclohexyl acrylate, methylcyclohexyl methacrylate, trimethylcyclohexyl acrylate, trimethylcyclohexyl methacrylate, butylcyclohexyl acrylate, butylcyclohexyl methacrylate, furfuryl acrylate, and furfuryl methacrylate; preferably isobornyl acrylate or isobornyl methacrylate.

It has been found that the cycloalkyl (meth)acrylate, preferably isobornyl acrylate or isobornyl methacrylate, inter alia increases T_{g} of the adhesive.

Preferably, the curable adhesive comprises essentially no cycloalkyl (meth)acrylate other than isobornyl methacrylate.

Preferably, the content of the cycloalkyl (meth)acrylate, preferably isobornyl acrylate or isobornyl methacrylate, is less than 5.5 wt.-%, more preferably at most 5.0 wt.-%, still more preferably at most 4.8 wt.-%, yet more preferably at most 4.6 wt.-%, even more preferably at most 4.4 wt.-%, most preferably at most 4.2 wt.-%, and in particular at most 4.0 wt.-%, in each case relative to the total weight of the curable adhesive.

Preferably, the content of the cycloalkyl (meth)acrylate, preferably isobornyl acrylate or isobornyl methacrylate, is within the range of 5.0±4.5 wt.-%, more preferably 5.0±4.0 wt.-%, still more preferably 5.0±3.5 wt.-%, yet more preferably 5.0±3.0 wt.-%, even more preferably 5.0±2.5 wt.-%, most preferably 5.0±2.0 wt.-%, and in particular 5.0±1.5 wt.-%, in each case relative to the total weight of the curable adhesive. When the curable adhesive comprises more than a single cycloalkyl (meth)acrylate, the specified content of cycloalkyl (meth)acrylate refers to the overall content of all cycloalkyl (meth)acrylates that are contained in the curable adhesive.

The curable adhesive according to the invention preferably comprises a hydroxy-C₁₋₆-alkyl (meth)acrylate, which is preferably selected from the group consisting of hydroxyethyl acrylate, hydroxyethyl methacrylate, hydroxypropyl acrylate, hydroxypropyl methacrylate, hydroxybutyl acrylate, and hydroxybutyl methacrylate; preferably hydroxyethyl (meth)acrylate or hydroxypropyl (meth)acrylate.

It has been found that the hydroxy-C₁₋₆-alkyl (meth)acrylate, preferably hydroxyethyl (meth)acrylate or hydroxypropyl (meth)acrylate, inter alia imparts flexibility to the adhesive

Preferably, the curable adhesive comprises essentially no hydroxy-C₁₋₆-alkyl (meth)acrylate other than hydroxyethyl methacrylate.

Preferably, the content of the hydroxy-C₁₋₆-alkyl (meth)acrylate, preferably hydroxyethyl (meth)acrylate or hydroxypropyl (meth)acrylate, is more than 6.0 wt.-%, more preferably at least 6.5 wt.-%, still more preferably at least 7.0 wt.-%, yet more preferably at least 7.5 wt.-%, even more preferably at least 8.0 wt.-%, most preferably at least 8.5 wt.-%, and in particular at least 9.0 wt.-%, in each case relative to the total weight of the curable adhesive.

Preferably, the content of the hydroxy-C₁₋₆-alkyl (meth)acrylate, preferably hydroxyethyl (meth)acrylate or hydroxypropyl (meth)acrylate, is within the range of 10±9.0 wt.-%, more preferably 10±8.0 wt.-%, still more preferably 10±7.0 wt.-%, yet more preferably 10±6.0 wt.-%, even more preferably 10±5.0 wt.-%, most preferably 10±4.0 wt.-%, and in particular 10±3.0 wt.-%, in each case relative to the total weight of the curable adhesive. When the curable adhesive comprises more than a single hydroxy-C₁₋₆-alkyl (meth)acrylate, the specified content of hydroxy-C₁₋₆-alkyl (meth)acrylate refers to the overall content of all hydroxy-C₁₋₆-alkyl (meth)acrylates that are contained in the curable adhesive.

The curable adhesive according to the invention preferably comprises a glycolether (meth)acrylate according to general formula (I), CH₂═CR—C(═O)—O—[CH₂CH₂—O]ₙ—CₘH₂ₘ₊₁, wherein R is —H or —CH₃, preferably —CH₃; wherein index n is an integer within the range of from 1 to 12, preferably 2; and wherein index m is an integer within the range of from 1 to 8, preferably 4.

Preferably, the glycolether (meth)acrylate according to general formula (I) is selected from the group consisting of methylmonoglycol (meth)acrylate, ethylmonoglycol (meth)acrylate, propylmonoglycol (meth)acrylate, butylmonoglycol (meth)acrylate, methyldiglycol (meth)acrylate, ethyldiglycol (meth)acrylate, propyldiglycol (meth)acrylate, butyldiglycol (meth)acrylate, methyltriglycol (meth)acrylate, ethyltriglycol (meth)acrylate, propyltriglycol (meth)acrylate, and butyltriglycol (meth)acrylate; preferably butyldiglycol methacrylate.

It has been found that the glycolether (meth)acrylate according to general formula (I), preferably butyldiglycol methacrylate, inter alia reduces bubble formation at short curing times and/or high gap-filling. The bubbles are reduced due to the low content of methyl methacrylate (preferably around 30 to 33%) which is possible by substituting a part of methyl methacrylate by glycolether (meth)acrylate according to general formula (I). The use of a mix of higher boiling point monomers compared to methyl methacrylate helps to reduce bubble formation.

Preferably, the curable adhesive comprises essentially no glycolether (meth)acrylate according to general formula (I) other than butyldiglycol methacrylate.

In a preferred embodiment, the content of the glycolether (meth)acrylate according to general formula (I), preferably butyldiglycol methacrylate, is within the range of 5.0±4.5 wt.-%, more preferably 5.0±4.0 wt.-%, still more preferably 5.0±3.5 wt.-%, yet more preferably 5.0±3.0 wt.-%, even more preferably 5.0±2.5 wt.-%, most preferably 5.0±2.0 wt.-%, and in particular 5.0±1.5 wt.-%, in each case relative to the total weight of the curable adhesive.

In another preferred embodiment, the content of the glycolether (meth)acrylate according to general formula (I), preferably butyldiglycol methacrylate, is within the range of 10±9.0 wt.-%, more preferably 10±8.0 wt.-%, still more preferably 10±7.0 wt.-%, yet more preferably 10±6.0 wt.-%, even more preferably 10±5.0 wt.-%, most preferably 10±4.0 wt.-%, and in particular 10±3.0 wt.-%, in each case relative to the total weight of the curable adhesive. When the curable adhesive comprises more than a single glycolether (meth)acrylate according to general formula (I), the specified content of glycolether (meth)acrylate according to general formula (I) refers to the overall content of all glycolether (meth)acrylates according to general formula (I) that are contained in the curable adhesive.

The curable adhesive according to the invention comprises a polymerization initiator, preferably a peroxide polymerization initiator, which is preferably selected from the group consisting of benzoyl peroxide, tertbutyl hydroperoxide, di-tertbutyl peroxide, cumene hydroperoxide, dicumene peroxide, tertbutyl peracetate, tertbutyl perbenzoate, and di-tertbutyl peroxide; preferably benzoyl peroxide or ditertbutyl peroxide.

Preferably, the curable adhesive comprises essentially no peroxide polymerization initiator other than benzoyl peroxide, preferably no radical polymerization initiator, other than benzoyl peroxide.

The curable adhesive according to the invention is preferably curable at room temperature (23°° C.), i.e. spontaneously starts curing once the first component and the second component of a two-component system have been mixed with one another. Nonetheless, it is also contemplated that curing may be accelerated by subjecting the mixture to elevated temperature.

Preferably, the content of the polymerization initiator is within the range of 3.5±3.4 wt.-%, more preferably 3.5±3.0 wt.-%, still more preferably 3.5±2.5 wt.-%, yet more preferably 3.5±2.0 wt.-%, even more preferably 3.5±1.5 wt.-%, most preferably 3.5±1.0 wt.-%, and in particular 3.5±0.5 wt.-%, in each case relative to the total weight of the curable adhesive. When the curable adhesive comprises more than a polymerization initiator, the specified content of polymerization initiator refers to the overall content of all polymerization initiators that are contained in the curable adhesive.

The cured adhesive preferably has a crosslink density of at least 1.102 mol/m³, preferably at least 1.103 mol/m³, more preferably at least 1.104 mol/m³, still more preferably at least 1.105 mol/m³, yet more preferably at least 1.106 mol/m³, even more preferably at least 1.107 mol/m³, most preferably at least 1.108 mol/m³, and in particular at least 1.109 mol/m³. The crosslink density of the cured adhesive is preferably determined according to the method described in D. R. Miller and Ch. W. Macosko, Macro-molecules, Vol. 9, No. 2, pages 206-211 (1976).

Preferably, the curable adhesive according to the invention comprises a first toughening agent and optionally and preferably, a second toughening agent that differs from the first toughening agent.

For the purpose of the specification, a toughening agent increases the ability of the adhesive to absorb energy and plastically deform without fracture. Typical toughening agents are rubbers (elastomers) that can be interspersed as nanoparticles within a polymer matrix to increase the mechanical robustness, or toughness, of the material. Toughening agents are known to the skilled person (see e.g. Bucknall C. B. (1977) Toughened Plastics, Springer; Keskkula H., Paul D. R. (1994) Toughening agents for engineering polymers. In: Collyer A. A. (eds) Rubber Toughened Engineering Plastics. Springer; Arends Ch. (1996) Polymer Toughning, Marcel Dekker).

Elastomers and polymers employed as toughening agents may have a glass transition temperature (T_{g}) of less than −25° C., and advantageously less than −50° C. Further, these toughening agents may beneficially be soluble in the acrylic monomers described above. In general, the elastomers may include synthetic high polymers. Moreover, the elastomers may be supplied commercially as adhesive grades. Elastomers and polymers may include polychloroprene (neoprene) and block-copolymers of butadiene or isoprene with styrene, acrylonitrile, acrylates, methacrylates, and the like.

Preferably, the first toughening agent is a liquid toughening agent, i.e. in isolated form at room temperature (23° C.) is a liquid. Preferably, the first toughening agent is a liquid olefinic-terminated elastomer such as homopolymers of butadiene, copolymers of butadiene and at least one monomer copolymerizable therewith, for example, styrene, acrylonitrile, methacrylonitrile (e.g. poly(butadiene-(meth)acrylonitrile or poly(butadiene-(meth)acrylonitrile-styrene) and mixtures thereof; as well as modified elastomeric polymeric materials, such as butadiene homopolymers and copolymers modified by copolymerization therewith of trace amounts of up to about 5 wt.-% of elastomeric material of at least one functional monomer (such as acrylic acid, methacrylic acid, maleic anhydride, fumaric acid, styrene, and methyl methacrylate to give, for example, methacrylate-terminated polybutadiene homopolymers and/or copolymers).

A preferred subgroup of olefinic-terminated elastomers according to the invention are (meth)acrylate-terminated elastomers where a terminal olefinic unsaturation is part of the terminal (meth)acrylate functional group.

Preferably, the first toughening agent is selected from (meth)acrylate terminated butadiene-acrylonitrile copolymers. (meth)acrylate (vinyl) terminated butadiene-acrylonitrile copolymers (commercially available e.g. as Hypro™ 2000X168LC VTB) and, (meth)acrylate-terminated poly(butadiene-acrylonitrile-acrylic acid) terpolymers; preferably a (meth)acrylate terminated butadiene-acrylonitrile copolymer. Preferably, the butadiene acrylonitrile backbone is a random copolymer backbone with a content of more than 50 wt.-% butadiene, more preferably at least 60 wt.-%, still more preferably at least 70 wt.-%, and in particular at least 80 wt.-%, the remainder being acrylonitrile. First toughening agents of this type are commercially available (e.g. Hypro™1300X33LC VTBNX, Hypro™ 1300X43VTBNX).

Preferably, the content of the first toughening agent is within the range of 8.0±7.5 wt.-%, more preferably 8.0±7.0 wt.-%, still more preferably 8.0±6.5 wt.-%, yet more preferably 8.0±6.0 wt.-%, even more preferably 8.0±5.5 wt.-%, most preferably 8.0±5.0 wt.-%, and in particular 8.0±4.5 wt.-%, or 8.0±4.0 wt.-%, or 8.0±3.5 wt.-%, or 8.0±3.0 wt.-%, or 8.0±2.5 wt.-%, or 8.0±2.0 wt.-%, in each case relative to the total weight of the curable adhesive.

Preferably, the second toughening agent is a solid toughening agent, i.e. in isolated form at room temperature (23°° C.) is a solid. Preferably, the second toughening agent is selected from styrene-butadiene-styrene block-copolymers (SBS), styrene-isoprene-styrene block-copolymers (SIS), styrene-ethylene-propylene block-copolymers (SEP), styrene-ethylene-butadiene-styrene block-copolymers (SEBS), ethylene-propylene rubbers (EPR), acrylonitrile-butadiene rubbers (NBR), ethylene propylene diene rubbers (EPDM), butadiene rubbers (BR), natural rubbers (NR), styrene-butadiene rubbers (SBR), thermoplastic polyolefin elastomers (POE), chlorinated polyethylenes, ethylene-acrylic acid copolymers (EAA), ethylene-vinyl acetate or a mixture of several ethylene copolymers (EVA); preferably a styrene-butadiene-styrene block-copolymer (SBS). Second toughening agents of this type are commercially available (e.g. Kraton™ D1102, Kraton™ D1116, Kraton™ D1118, Kraton™ D1133, Kraton™ D1152 ESM, Kraton™ D1153, Kraton™ D1155, Kraton™ D1192).

Preferred second toughening agents include copolymers (e.g., block-copolymers) having a glass transition temperature, T_{g}, of at least one domain in the range of in the range of −50° C. to −110° C. Embodiments of these toughening agents include styrene-butadiene-styrene (SBS) copolymers. Commercial examples of SBS copolymers are Kraton™M D1116, Kraton D1152 ESM and Kratone™ 1184.

Preferably, the curable adhesive according to the invention essentially does not contain any copolymer or block-copolymer selected from the group consisting of styrene-butadiene rubber (SBR) [other than SBS], styrene-ethylene-butadiene-styrene (SEBS), styrene-isoprene-styrene (SIS), acrylonitrile butadiene styrene copolymers (ABS), acrylonitrile styrene acrylate copolymers (ASA), acrylonitrile-ethylene-propylene-diene-styrene (AES), styrene acrylonitrile (SAN), methyl methacrylate-butadiene-styrene (MBS), and styrene-acrylonitrile (SAN).

Preferably, the content of second toughening agent is within the range of 7.0±6.5 wt.-%, more preferably 7.0±6.0 wt.-%, still more preferably 7.0±5.5 wt.-%, yet more preferably 7.0±5.0 wt.-%, even more preferably 7.0±4.5 wt.-%, most preferably 7.0±4.0 wt.-%, or 7.0±3.5 wt.-%, or 7.0±3.0 wt.-%, or 7.0±2.5 wt.-%, or 7.0±2.0 wt.-%, and in particular 7.0±1.0 wt.-%, in each case relative to the total weight of the curable adhesive.

Preferably, the curable adhesive according to the invention comprises a first impact modifier and optionally and preferably, a second impact modifier that differs from the first impact modifier.

For the purpose of the specification, an impact modifier increases the durability of the adhesive. Impact modifiers are known to the skilled person (see e.g. Berzins A. P. Impact Modifiers, Chapter 8 in Lutz J. T., Grossmann R. F. Polymer Modifiers and Adhesives (2001), Marcel Dekker).

The adhesives formulated with impact modifiers exhibit desirable properties for many adhesive applications. For example, impact modifiers have a similar effect on the cured adhesives as toughening agents in reducing brittleness and increasing impact strength of the cured adhesives. The impact modifiers may also provide improved non-sag and thixotropic properties, and anti-sliding performance in the uncured adhesives.

The impact modifiers according to the invention generally include graft copolymers that may be characterized as core-shell copolymers having a rubbery “core,” a hard “shell,” and that swell in the methacrylate and/or acrylate monomer compositions but do not dissolve therein. Examples of core-shell copolymers are those where the hard “shell” monomers, such as styrene, acrylonitrile, or methyl methacrylate, are grafted onto a rubbery “core” made from polymers of butadiene, butyl acrylate, ethyl acrylate, isoprene and the like. One type of core-shell polymers is methacrylate butadiene styrene (MBS) copolymer made by polymerizing methyl methacrylate in the presence of polybutadiene or a polybutadiene copolymer rubber. Commercial examples of core shell impact modifiers are Paraloid™ BTA-753, Paraloid 2650A, Paraloid 2691A, Clearstrength® E920, Clearstrength XT 100, and Kane Ace™ B-564 or Kane Ace™ M521.

Preferably, the total content of the first impact modifier and the second impact modifier is at least 10 wt.-%, or at least 12.5 wt.-%, more preferably at least 15 wt.-%, still more preferably at least 17.5 wt.-%, yet more preferably at least 20 wt.-%, most preferably at least 22.5 wt.-%, and in particular at least 25 wt.-%, in each case relative to the total weight of the curable adhesive.

The first toughening agent, the second toughening agent, the first impact modifier and the second impact modifier differ from one another.

Preferably, the first impact modifier is a first core shell impact modifier; preferably a core shell impact modifier having an all-acrylic core shell based on butyl-acrylate rubber. Thus, the first impact modifier preferably is a core-shell copolymer where hard “shell” acrylate monomers (preferably (methyl)methacrylates) are grafted onto a rubbery “core” made from butyl acrylate rubber. First impact modifiers of this type are commercially available (e.g. Paraloid™ EXL-2300G, Paraloid EXL-2314, Paraloid EXL 3361).

Preferably, the content of the first impact modifier is within the range of 5.0±4.5 wt.-%, more preferably 5.0±4.0 wt.-%, still more preferably 5.0±3.5 wt.-%, yet more preferably 5.0±3.0 wt.-%, even more preferably 5.0±2.5 wt.-%, most preferably 5.0±2.0 wt.-%, and in particular 5.0±1.5 wt.-%, in each case relative to the total weight of the curable adhesive.

Preferably, the second impact modifier is a second core shell impact modifier. Preferably, the second impact modifier is selected from impact modifiers based on butadiene, isoprene, ethylene-propylene and ethylene-butylene in combination with styrene, acrylonitrile and acrylic monomers; acrylonitrile butadiene styrene (ABS) impact modifiers; methacrylate butadiene styrene (MBS) impact modifiers; and MABS impact modifiers. In a preferred embodiment, the second impact modifier is a (methyl)methacrylate butadiene styrene (MBS) core shell impact modifier. Thus, the second impact modifier preferably is a core-shell copolymer where hard “shell” acrylate monomers (preferably (methyl)methacrylates) are grafted onto a rubbery “core” made from butadiene styrene rubber. Second impact modifiers of this type are commercially available (e.g. Kane Ace™ B564, Kane Ace™ M521, Clearstrength™ XT 100, Paraloid 2650A, Paraloid 2691A, Clearstrength® E920, Clearstrength XT 100). In another preferred embodiment, the second impact modifier is a core shell polybutadiene rubber, which may be dispersed in liquid bisphenol A epoxy resin (e.g. Kane Ace™ MX257).

Preferably, the content of the second impact modifier is within the range of 25±23 wt.-%, more preferably 25±20 wt.-%, still more preferably 25±17 wt.-%, yet more preferably 25±15 wt.-%, or 25±13 wt.-%, even more preferably 25±11 wt.-%, or 25±10 wt.-%, most preferably 25±8.0 wt.-%, and in particular 25±5.0 wt.-%, or 25±4.0 wt.-%, in each case relative to the total weight of the curable adhesive.

Preferably, the curable adhesive according to the invention comprises a combination of a
a first toughening agent selected from (meth)acrylate terminated butadiene-acrylonitrile copolymers, (meth)acrylate (vinyl) terminated butadiene-acrylonitrile copolymers and (meth)acrylate-terminated poly(butadiene-acrylonitrile-acrylic acid) terpolymers; preferably a (meth)acrylate terminated butadiene-acrylonitrile copolymer; and
a second toughening agent selected from SBS, SIS, SEP, SEBS, EPR, NBR, EPDM, BR, NR, SBR, POE, CI-PE, EAA, and EVA; preferably a styrene-butadiene-styrene block-copolymer (SBS); and
a first impact modifier being a first core shell impact modifier; preferably a core shell impact modifier having an all-acrylic core shell based on butyl-acrylate rubber; and
a second impact modifier being a second core shell impact modifier; preferably selected from impact modifiers based on butadiene, isoprene, ethylene-propylene and ethylene-butylene in combination with styrene, acrylonitrile and acrylic monomers; ABS impact modifiers; MBS impact modifiers; and MABS impact modifiers; preferably a (methyl)methacrylate butadiene styrene (MBS) core shell impact modifier.

In a preferred embodiment, the curable adhesive according to the invention comprises a first toughening agent selected from (meth)acrylate terminated butadiene-acrylonitrile copolymers, (meth)acrylate (vinyl) terminated butadiene-acrylonitrile copolymers and (meth)acrylate-terminated poly(butadiene-acrylonitrile-acrylic acid) terpolymers; preferably a (meth)acrylate terminated butadiene-acrylonitrile copolymer and a second toughening agent selected from SBS, SIS, SEP, SEBS, EPR, NBR, EPDM, BR, NR, SBR, POE, CI-PE, EAA, and EVA; preferably a styrene-butadiene-styrene block-copolymer (SBS), wherein preferably the relative weight ratio of the first toughening agent to the second toughening agent is within the range of 7:1 to 1:7, more preferably 6:1 to 1:6, still more preferably 5:1 to 1:5, yet more preferably 4:1 to 1:4, even more preferably 3:1 to 1:3, most preferably 2:1 to 1:2, and in particular 1.5:1 to 1:1.5.

Preferably, the total content of impact modifiers (first impact modifier+second impact modifier+any potentially present additional impact modifier) is within the range of 27±23 wt.-%, more preferably 27±20 wt.-%, still more preferably 27±17 wt.-%, yet more preferably 27±15 wt.-%, or 27±13 wt .-%, even more preferably 27±11 wt.-%, or 27±10 wt.-%, most preferably 27±8.0 wt.-%, and in particular 27±5.0 wt.-%, or 27±4.0 wt.-%, in each case relative to the total weight of the curable adhesive.

In a preferred embodiment, the curable adhesive according to the invention comprises a first toughening agent selected from (meth)acrylate terminated butadiene-acrylonitrile copolymers, (meth)acrylate (vinyl) terminated butadiene-acrylonitrile copolymers and (meth)acrylate-terminated poly(butadiene-acrylonitrile-acrylic acid) terpolymers; preferably a (meth)acrylate terminated butadiene-acrylonitrile copolymer and a first impact modifier being a first core shell impact modifier; preferably a core shell impact modifier having an all-acrylic core shell based on butyl-acrylate rubber, wherein preferably the relative weight ratio of the first toughening agent to the first impact modifier is within the range of (3±2.8):1, more preferably (3±2.5):1, still more preferably (3±2.2):1, yet more preferably (3±1.9):1, even more preferably (3±1.6):1, most preferably (3±1.3):1, and in particular (3±1.0):1.

In a preferred embodiment, the curable adhesive according to the invention comprises a first toughening agent selected from (meth)acrylate terminated butadiene-acrylonitrile copolymers, (meth)acrylate (vinyl) terminated butadiene-acrylonitrile copolymers and (meth)acrylate-terminated poly(butadiene-acrylonitrile-acrylic acid) terpolymers; preferably a (meth)acrylate terminated butadiene-acrylonitrile copolymer and a second impact modifier being a second core shell impact modifier; preferably selected from impact modifiers based on butadiene, isoprene, ethylene-propylene and ethylene-butylene in combination with styrene, acrylonitrile and acrylic monomers; ABS impact modifiers; MBS impact modifiers; and MABS impact modifiers; preferably a (methyl)methacrylate butadiene styrene (MBS) core shell impact modifier, wherein preferably the relative weight ratio of the first toughening agent to the second impact modifier is within the range of 1:(3±2.8), more preferably 1:(3±2.5), still more preferably 1:(3±2.2), yet more preferably 1:(3±1.9), even more preferably 1:(3±1.6), most preferably 1:(3±1.3), and in particular 1:(3±1.0).

In a preferred embodiment, the curable adhesive according to the invention comprises a second toughening agent selected from SBS, SIS, SEP, SEBS, EPR, NBR, EPDM, BR, NR, SBR, POE, CI-PE, EAA, and EVA; preferably a styrene-butadiene-styrene block-copolymer (SBS)and a first impact modifier being a first core shell impact modifier; preferably a core shell impact modifier having an all-acrylic core shell based on butyl-acrylate rubber, wherein preferably the relative weight ratio of the second toughening agent to the first impact modifier is within the range of within the range of (2±1.8): 1, more preferably (2±1.6):1, still more preferably (2±1.4):1, yet more preferably (2±1.3): 1, even more preferably (2±1.0):1, most preferably (2±0.8):1, and in particular (2±0.6):1.

In a preferred embodiment, the curable adhesive according to the invention comprises a second toughening agent selected from SBS, SIS, SEP, SEBS, EPR, NBR, EPDM, BR, NR, SBR, POE, CI-PE, EAA, and EVA; preferably a styrene-butadiene-styrene block-copolymer (SBS)and a second impact modifier being a second core shell impact modifier; preferably selected from impact modifiers based on butadiene, isoprene, ethylene-propylene and ethylene-butylene in combination with styrene, acrylonitrile and acrylic monomers; ABS impact modifiers; MBS impact modifiers; and MABS impact modifiers; preferably a (methyl)methacrylate butadiene styrene (MBS) core shell impact modifier, wherein preferably the relative weight ratio of the second toughening agent to the second impact modifier is within the range of 1:(3±2.8), more preferably 1:(3±2.5), still more preferably 1:(3±2.2), yet more preferably 1:(3±1.9), even more preferably 1:3(±1.6), most preferably 1:3(±1.3), and in particular 1:3(±1.0).

In a preferred embodiment, the curable adhesive according to the invention comprises a first impact modifier being a first core shell impact modifier; preferably a core shell impact modifier having an all-acrylic core shell based on butyl-acrylate rubber and a second impact modifier being a second core shell impact modifier; preferably selected from impact modifiers based on butadiene, isoprene, ethylene-propylene and ethylene-butylene in combination with styrene, acrylonitrile and acrylic monomers; ABS impact modifiers; MBS impact modifiers; and MABS impact modifiers; preferably a (methyl)methacrylate butadiene styrene (MBS) core shell impact modifier, wherein preferably the relative weight ratio of the first impact modifier to the second impact modifier is within the range of 1:(3±2.8), more preferably 1:(3±2.5), still more preferably 1:(3±2.2), yet more preferably 1:(3±1.9), even more preferably 1:(3±1.6), most preferably 1:(3±1.3), and in particular 1:(3±1.0).

In a preferred embodiment, the curable adhesive according to the invention comprises
a first impact modifier being a first core shell impact modifier; preferably a core shell impact modifier having an all-acrylic core shell based on butyl-acrylate rubber; wherein the first impact modifier is preferably contained in the first component;
a second impact modifier being a second core shell impact modifier; preferably selected from impact modifiers based on butadiene, isoprene, ethylene-propylene and ethylene-butylene in combination with styrene, acrylonitrile and acrylic monomers; ABS impact modifiers; MBS impact modifiers; and MABS impact modifiers; preferably a (methyl)methacrylate butadiene styrene (MBS) core shell impact modifier; wherein the second impact modifier is preferably contained in the first component; and
a third impact modifier being a third core shell impact modifier, preferably a polybutadiene rubber, which may be dispersed in liquid bisphenol A epoxy resin; wherein the third impact modifier is preferably contained in the second component.

According to this above preferred embodiment, the relative weight ratio of the first impact modifier to the second impact modifier to the third impact modifier is preferably within the range of 1:(6±2.0):(2±1.9), more preferably 1:(6±1.8):(2±1.9), still more preferably 1:(6±1.6):(2±1.9), yet more preferably 1:(6±1.4):(2±1.9), even more preferably 1:(6±1.2):(2±1.9), most preferably 1:(6±1.0):(2±1.9), and in particular 1:(6±0.8):(2±1.9); or 1:(6±2.0):(2±1.9), more preferably 1:(6±2.0):(2±1.9), still more preferably 1:(6±2.0):(2±1.9), yet more preferably 1:(6±2.0):(2±1.9), even more preferably 1:(6±2.0):(2±1.9), most preferably 1:(6±2.0):(2±1.9), and in particular 1:(6±2.0):(2±1.9); or 1:(6±2.0):(2±0.7), more preferably 1:(6±1.8):(2±0.9), still more preferably 1:(6±1.6):(2±1.1), yet more preferably 1:(6±1.4):(2±1.3), even more preferably 1:(6±1.2):(2±1.5), most preferably 1:(6±1.0):(2±1.7), and in particular 1:(6±0.8):(2±1.9).

Preferably, the curable adhesive according to the invention additionally comprises an accelerator; preferably a metal di(meth)acrylate; more preferably a metal di(meth)acrylate selected from zinc di(meth)acrylate, aluminum di(meth)acrylate and magnesium di(meth)acrylate; most preferably zinc di-acrylate or zinc dimethacrylate. Further accelerators include but are not limited to organic transitional metal compounds, such as copper acetyl acetonate, vanadium acetyl acetonate, and the like. In general, the accelerators may be organic salts of a transition metal, such as cobalt, nickel, manganese or iron naphthenate, copper octoate, copper acetylacetonate, iron hexoate, iron propionate, and the like. Accelerators are commercially available (e.g. Dymalink™ 708, Dymalink™ 709).

In a preferred embodiment, the curable adhesive according to the invention does not contain a metal di(meth)acrylate accelerator.

As the polymerization initiator is contained in the second component of the two-component system and as the polymerization accelerator is preferably present spatially separate from the initiator to prevent premature polymerization (curing), the accelerator is preferably contained in the first component of the two-component system.

Preferably, the content of the accelerator is within the range of 1.0±0.9 wt.-%, more preferably 1.0±0.8 wt.-%, still more preferably 1.0±0.7 wt.-%, yet more preferably 1.0±0.6 wt.-%, even more preferably 1.0±0.5 wt.-%, most preferably 1.0±0.4 wt.-%, and in particular 1.0±0.3 wt.-%, in each case relative to the total weight of the curable adhesive. When the curable adhesive comprises more than a single accelerator, the specified content of accelerator refers to the overall content of all accelerators that are contained in the curable adhesive.

Curatives (or curing agents) may be employed to formulate fast cure adhesives. Preferably, the curable adhesive according to the invention additionally comprises a curative; preferably a curative selected from N,N-dimethyl-para-toluidine (DMPT), N-(2-hydroxyethyl)-N-methyl-para-toluidine (MHPT), N-methyl-N-(2-hydroxypropyl)-p-toluidine (2HPMT), and N-ethyl-N-(2-hydroxyethyl)-p-toluidine (EHPT); more preferably N-methyl-para toluidine derivatives, N-(2-hydroxyethyl)-N-methyl-para-toluidine, N-ethyl-N-(2-hydroxyethyl)-p-toluidine, or any combination thereof. Curatives are commercially available (e.g. Firstcure™ MHPT).

Preferably, the content of the curative is within the range of 1.0±0.9 wt.-%, more preferably 1.0±0.8 wt.-%, still more preferably 1.0±0.7 wt.-%, yet more preferably 1.0±0.6 wt.-%, even more preferably 1.0±0.5 wt.-%, most preferably 1.0±0.4 wt.-%, and in particular 1.0±0.3 wt.-%, in each case relative to the total weight of the curable adhesive. When the curable adhesive comprises more than a single curative, the specified content of curative refers to the overall content of all curatives that are contained in the curable adhesive.

Preferably, the curable adhesive according to the invention additionally comprises an adhesion promoter; preferably a phosphate-ester-based adhesion promoter; more preferably an adhesion promoter selected from the group consisting of 2-methacryloyloxyethyl phosphate, bis(2-methacryloyl-oxyethyl phosphate), 2-acryloyloxyethyl phosphate, bis(2-acryloyloxyethyl phosphate), methyl-(2-meth-acryloyloxyethyl phosphate), ethyl-(2-methacryloyl-oxyethyl phosphate), and mixtures of 2-hydroxyethyl methacrylate monophosphate and diphosphate esters; most preferably (meth)acrylate phosphate esters such as 2-hydroxyethyl methacrylate phosphate ester, 2-hydroxyethyl acrylate phosphate ester, or any combination thereof. Suitable phosphate-ester-based adhesion promoters are commercially available (e.g. Miramer™ A99, Miramer™ SC1400).

In a preferred embodiment, the curable adhesive according to the invention does not contain a phosphate-ester-based adhesion promoter.

Preferably, the content of the adhesion promoter is within the range of 2.5±2.4 wt.-%, more preferably 2.5±2.2 wt.-%, still more preferably 2.5±2.0 wt.-%, yet more preferably 2.5±1.8 wt.-%, even more preferably 2.5±1.6 wt.-%, or 2.5±1.5 wt.-%, most preferably 2.5±1.4 wt.-%, and in particular 2.5±1.2 wt.-%, or 2.5±1.0 wt.-%, in each case relative to the total weight of the curable adhesive. When the curable adhesive comprises more than a single adhesion promoter, the specified content of adhesion promoter refers to the overall content of all adhesion promoters that are contained in the curable adhesive.

Preferably, the curable adhesive according to the invention additionally comprises a cure indicator; preferably a triphenylmethane derivative, e.g. bis(dimethylamino)triphenylmethane or tris(dimethylamino)triphenylmethane. Cure indicators change their color during the polymerization and curing reaction thereby visually indicating the progress of polymerization and curing. Suitable cure indicators are disclosed in e.g. WO 98/34980 and US 2013/292054, both incorporated by reference.

Preferably, the content of the cure indicator is at most 0.10 wt.-%, more preferably at most 0.09 wt.-%, still more preferably at most 0.08 wt.-%, yet more preferably at most 0.07 wt.-%, even more preferably at most 0.06 wt.-%, most preferably at most 0.05 wt.-%, in each case relative to the total weight of the curable adhesive. Preferably, the cure indicator is contained at a concentration that is so low that the cure indicator as such has no influence of the progress of the polymerization and curing reaction.

Preferably, the curable adhesive according to the invention additionally comprises a stabilizer (sometimes also referred to as inhibitor or retardant); preferably a stabilizer selected from the group consisting of phenols, quinones, hydroquinones, thiazines, phenothiazines, N-oxyls, aromatic amines, phenylenediamines, sulfonamides, oximes, hydroxylamines, urea derivatives, phosphorus compounds, sulfur compounds and metal salts; more preferably hydroquinone derivatives such as methyl ethers of hydroquinones, e.g. mono-tert-butyl hydroquinone (MTBHQ), monomethylether of hydroquinone, di-tert-butyl hydroquinone (DTBHQ), or 2,6-di-tert-butyl-4-methylphenol, 6-di-tert-butyl-4-(dimethylaminomethyl)phenol, phenothiazine derivatives such as 10H-phenothiazine, or any combination thereof.

Such stabilizers are normally used to prevent premature polymerization and curing and to help the radical polymerization initiator to provide for a desired and consistent cure profile, and thus a consistent working time. Further examples include but are not limited to combinations of butylated hydroxytoluene (BHT or 2,6-di-tert-butyl-p-cresol) and quinone(s), which commonly may be employed for medium and long open time adhesives. A specific example of an inhibitor/retardant system is a combination of butylated hydroxytoluene (BHT) and hydroquinone (HQ).

Preferably, the content of the stabilizer is within the range of 0.001 to 2.0 wt.-%, more preferably 0.001 to 1.0 wt.-%, still more preferably 0.001 to 0.5 wt.-%, in each vase relative to the total weight of the curable adhesive.

Preferably, the curable adhesive according to the invention additionally comprises a filler; preferably an inorganic filler.

Preferably, the filler has the form of flakes, platelets, rods, needles, rectangles, and/or microspheres.

Preferably, the filler is selected from the group consisting of MgO, CaO, BaO, K₂O, Li₂O, Na₂O, SiO₂, carbonates, preferably calcium carbonate; silicates, borates, titanium oxide, hydroxides, preferably aluminum hydroxide; sulfates, carbon black, the pigments used to color material and mixtures thereof; preferably silicates.

In preferred embodiments, the filler comprises a silicate mineral selected from the group consisting of phyllosilicates, inosilicates, nesosilicates, sorosilicates, cyclosilicates, tectosilicates, and mixtures thereof; preferably phyllosilicates, inosilicates, nesosilicates and mixtures thereof.

Preferably, the filler comprises an inosilicate selected from pyroxenes; preferably wollastonite, rhodonite, or pectolite.

Preferably, the filler comprises a phyllosilicate selected from clay minerals, micas and mixtures thereof; preferably talc, kaolinite, montmorillonite, sepiolite, phlogopite, muscovite and mixtures thereof; more preferably kaolinite, muscovite and mixtures thereof; still more preferably muscovite and mixtures thereof.

In preferred embodiments, the filler comprises two micas having different particle size distributions; preferably muscovite micas. Preferably, a first mica comprises particles having
a volume median diameter D30 within the range of 2.0±1.8 μm, preferably 2.0±1.0 μm;
a volume median diameter D50 within the range of 4.0±3.8 μm, preferably 4.0±2.0 μm; and/or
a volume median diameter D90 within the range of 9.0±8.0 μm, preferably 9.0±5.0 μm; and a second mica comprises particles having
a volume median diameter D30 within the range of 5.5±5.0 μm, preferably 5.5±2.0 μm;
a volume median diameter D50 within the range of 7.5±7.0 μm, preferably 7.5±3.0 μm; and/or
a volume median diameter D90 within the range of 16±10 μm, preferably 16±6.0 μm.

Preferably, the filler comprises an aluminosilicate; preferably aluminosilicate microspheres.

Preferably, the filler comprises an organically modified phyllosilicate; preferably organophilic phyllosilicate.

Preferably, the filler comprises a phosphosilicate; preferably zinc phosphosilicate; more preferably organically modified zinc phosphosilicate.

In preferred embodiments, the filler comprises or essentially consists of a mixture of two or more silicates; preferably a phyllosilicate and an aluminosilicate; more preferably an organically modified phyllosilicate and an aluminosilicate; still more preferably organophilic phyllosilicate and aluminosilicate microspheres.

In other preferred embodiments, the filler comprises or essentially consists of a mixture of two or more silicate minerals; preferably two or more phyllosilicates; more preferably an organically modified phyllosilicate and mica; still more preferably organophilic phyllosilicate and muscovite; yet more preferably organophilic phyllosilicate and two micas having different particle size distributions. Preferably, a first mica comprises particles having
a volume median diameter D30 within the range of 2.0±1.8 μm, preferably 2.0±1.0 μm;
a volume median diameter D50 within the range of 4.0±3.8 μm, preferably 4.0±2.0 μm; and/or
a volume median diameter D90 within the range of 9.0±8.0 μm, preferably 9.0±5.0 μm; and a second mica comprises particles having
a volume median diameter D30 within the range of 5.5±5.0 μm, preferably 5.5±2.0 μm;
a volume median diameter D50 within the range of 7.5±7.0 μm, preferably 7.5±3.0 μm; and/or
a volume median diameter D90 within the range of 16±10 μm, preferably 16±6.0 μm.

Preferably, the filler comprises particles, preferably aluminosilicate particles, more preferably aluminosilicate microspheres, with a polydisperse particle size distribution; preferably with an average particle size range of from 1.0 to 500 μm; more preferably from 2.0 to 300 μm, still more preferably from 3.0 to 180 μm, yet more preferably from 4.0 to 150 μm, and even more preferably from 5.0 to 106 μm; determined by centrifugal liquid sedimentation according to ISO 13318.

Preferably, at least 90 wt.-% of the particles, preferably aluminosilicate particles, more preferably aluminosilicate microspheres, within the filler have a particle size of at most 500 μm, preferably at most 300 μm, more preferably at most 180 μm, still more preferably at most 150 μm, and yet more preferably at most 106 μm; determined by centrifugal liquid sedimentation according to ISO 13318.

Preferably, at least 10 wt.-% of the particles, preferably aluminosilicate particles, more preferably aluminosilicate microspheres, within the filler have a particle size of at most 100 μm, preferably at most 50 μm; determined by centrifugal liquid sedimentation according to ISO 13318.

Preferably, the filler comprises particles having an average particle size of
at least 1.0 μm, preferably at least 1.5 μm, more preferably at least 2.0 μm, still more preferably at least 2.5 μm, yet more preferably at least 3.0 μm, even more preferably at least 3.5 μm, most preferably at least 4.0 μm, and in particular at least 4.5 μm;
at most 22.5 μm, preferably at most 20 μm, more preferably at most 17.5 μm, still more preferably at most 15 μm, yet more preferably at most 12.5 μm, even more preferably at most 10 μm, most preferably at most 7.5 μm, and in particular at most 5.0 μm; and/or
within the range of 5.0±4.8 μm, preferably 5.0±2.4 μm;
in each case determined by centrifugal liquid sedimentation according to ISO 13318.

Preferably, the filler comprises particles having a volume median diameter D30 of
at least 1.5 μm, preferably at least 2.0 μm, more preferably at least 2.5 μm, still more preferably at least 3.0 μm, yet more preferably at least 3.5 μm, even more preferably at least 4.0 μm, most preferably at least 4.5 μm, and in particular at least 5.0 μm;
at most 35 μm, preferably at most 30 μm, more preferably at most 25 μm, still more preferably at most 20 μm, yet more preferably at most 15 μm, even more preferably at most 7.5 μm, most preferably at most 5.0 μm, and in particular at most 2.5 μm; and/or
within the range of 2.0±1.8 μm, preferably 2.0±1.0 μm; or 5.5±5.0 μm, preferably 5.5±2.0 μm;
in each case determined by centrifugal liquid sedimentation according to ISO 13318.

Preferably, the filler comprises particles having a volume median diameter D50 of
at least 0.5 μm, preferably at least 1.0 μm, more preferably at least 2.0 μm, still more preferably at least 3.0 μm, yet more preferably at least 4.0 μm, even more preferably at least 5.0 μm, most preferably at least 6.0 μm, and in particular at least 7.0 μm;
at most 35 μm, preferably at most 30 μm, more preferably at most 25 μm, still more preferably at most 20 μm, yet more preferably at most 15 μm, even more preferably at most 10 μm, most preferably at most 7.5 μm, and in particular at most 5.0 μm; and/or
within the range of 4.0±3.8 μm, preferably 4.0±2.0 μm; or 7.5±7.0 μm, preferably 7.5±3.0 μm;
   in each case determined by centrifugal liquid sedimentation according to ISO 13318.

Preferably, the filler comprises particles having a volume median diameter D90 of
at least 2.0 μm, preferably at least 4.0 μm, more preferably at least 6.0 μm, still more preferably at least 8.0 μm, yet more preferably at least 10 μm, even more preferably at least 12 μm, most preferably at least 14 μm, and in particular at least 16 μm;
at most 45 μm, preferably at most 40 μm, more preferably at most 35 μm, still more preferably at most 30 μm, yet more preferably at most 25 μm, even more preferably at most 20 μm, most preferably at most 15 μm, and in particular at most 10 μm; and/or
within the range of 9.0±8.0 μm, preferably 9.0±5.0 μm; or 16±10 μm, preferably 16±6.0 μm;
   in each case determined by centrifugal liquid sedimentation according to ISO 13318.

For the purpose of the specification, the term median diameter refers to the volume median diameter of the particle size distribution. Values D30, D50 and D90 indicate that 30%, 50% and 90% of the particles, respectively, are smaller than the specified values. The volume median diameter can for example be determined by means of a SediGraph®. The skilled person knows how to calibrate the measuring device and suitable calibration samples are commercially available.

Preferably, the filler comprises particles having an oil absorption number of
at least 6.0 g/100 g, preferably at least 10 g/100 g, more preferably at least 14 g/100 g, still more preferably at least 18 g/100 g, yet more preferably at least 22 g/100 g, even more preferably at least 26 g/100 g, most preferably at least 30 g/100 g, and in particular at least 34 g/100 g;
at most 64 g/100 g, preferably at most 60 g/100 g, more preferably at most 56 g/100 g, still more preferably at most 52 g/100 g, yet more preferably at most 48 g/100 g, even more preferably at most 44 g/100 g, most preferably at most 40 g/100 g, and in particular at most 36 g/100 g; and/or
within the range of 34±20 g/100 g, preferably 34±5.0 g/100 g;
   in each case determined according to DIN EN ISO 787-5.

In preferred embodiments, the filler comprises aluminum hydroxide; preferably precipitated aluminum hydroxide.

In preferred embodiments, the filler comprises borosilicate glass; preferably borosilicate glass powder.

Preferably, the filler is selected from kaolin, silica, talc, calcium carbonate, carbon black, titanium oxides, and the pigments used to color material; most preferably bentonite clays, kaolinite clays such as kaolin, metakaolin, or any combination thereof. Preferably, the filler is thixotropic.

In a preferred embodiment of the invention, the viscosity of the first component and/or the second component is controlled by adjusting type and amount of first impact modifier and optionally, second modifier. According to this embodiment, the nature and amount of filler preferably does not or not significantly contribute to the viscosity of the first component and/or the second component. According to this embodiment, the filler essentially may serve the purposes of reducing costs, providing color (pigment), improving reinforcement (e.g. fibers), and the like.

In another preferred embodiment of the invention, the viscosity of the first component and/or the second component is controlled by adjusting type and amount of filler. According to this embodiment, thixotropic fillers are preferred.

In preferred embodiments, the content of the filler is
at least 3.0 wt.-%, preferably at least 4.0 wt.-%, more preferably at least 5.0 wt.-%, still more preferably at least 6.0 wt.-%, yet more preferably at least 7.0 wt.-%, even more preferably at least 8.0 wt.-%, most preferably at least 9.0 wt.-%, and in particular at least 10 wt.-%;
at most 24 wt.-%, preferably at most 22 wt.-%, more preferably at most 20 wt.-%, still more preferably at most 18 wt.-%, yet more preferably at most 16 wt.-%, even more preferably at most 14 wt.-%, most preferably at most 12 wt.-%, and in particular at most 10 wt.-%; and/or
within the range of 9.0±8.0 wt.-%, preferably 9.0±4.0 wt.-%;
   in each case relative to the total weight of the curable adhesive.

In preferred embodiments, the content of the filler is not more than 25 wt.-%, more preferably not more than 20 wt.-%, still more preferably not more than 17.5 wt.-%, yet more preferably not more than 15 wt.-%, even more preferably not more than 12.5 wt.-%, most preferably not more than 10 wt.-%, and in particular not more than 7.5 wt.-%, in each case relative to the total weight of the curable adhesive. In preferred embodiments, the content of the filler is not more than 5.0 wt.-%, more preferably not more than 4.5 wt.-%, still more preferably not more than 4.0 wt.-%, yet more preferably not more than 3.5 wt.-%, even more preferably not more than 3.0 wt.-%, most preferably not more than 2.5 wt.-%, and in particular not more than 2.0 wt.-%, in each case relative to the total weight of the curable adhesive

Preferably, the content of the filler is within the range of 5.0±4.8 wt.-%, more preferably 5.0±4.4 wt.-%, still more preferably 5.0±4.0 wt.-%, yet more preferably 5.0±3.6 wt.-%, even more preferably 5.0±3.2 wt.-%, most preferably 5.0±2.8 wt.-%, and in particular 5.0±2.4 wt.-%, in each case relative to the total weight of the curable adhesive.

In preferred embodiments, the filler is contained in the first component.

Preferably, the curable adhesive according to the invention additionally comprises a polymer; preferably a polyester, polyamide, polyurethane, cellulose ether, epoxy resin (e.g. diglycidylethers of bisphenol such as bisphenol F), polyolefin, or any combination thereof.

Preferably, the epoxy resin comprises epoxy functional groups that are capable of reacting e.g. with the carboxylic acid functional groups of the (meth)acrylic acid. In order to avoid premature reaction, the epoxy resin is preferably contained in the second component, i.e. spatially separate from the (meth)acrylic acid that is contained in the first component. Liquid diglycidylethers of bisphenol F are preferred.

Exemplary epoxy resins include but are not limited to phenolic resins, which may be a novolac type or other type resin. Other preferred epoxy resins include bisphenol-A epichlorohydrin ether polymer, or a bisphenol-A epoxy resin which may be modified with butadiene or another polymeric additive, or bisphenol-F-type epoxy resins. Moreover, various mixtures of several different epoxy resins may be employed as well. Examples of suitable epoxy resins are sold under the tradename DER330, DER331, Araldite™ GY 250, Araldite™ GY 260, Araldite™ GY 282, Araldite™ GY 281, Araldite™ GY 285, YD128, Epikote™ 828, DER 354, Epikote™ 862, Epikote™ 864, Epikote™ 869.

Preferably, the content of the polymer is within the range of 3.0±2.8 wt.-%, more preferably 3.0±2.5 wt.-%, still more preferably 3.0±2.2 wt.-%, yet more preferably 3.0±1.9 wt.-%, even more preferably 3.0±1.5 wt.-%, most preferably 3.0±1.2 wt.-%, and in particular 3.0±0.9 wt.-%, in each case relative to the total weight of the curable adhesive.

Preferably, the relative weight ratio of the first component to the second component is within the range of from 20:1 to 1:1, preferably 18:1 to 2:1, more preferably 16:1 to 4:1, still more preferably 15:1 to 5:1, yet more preferably 14:1 to 6:1, even more preferably 13:1 to 7:1, most preferably 12:1 to 8:1, and in particular 11:1 to 9:1.

Preferably, the relative volume ratio of the first component to the second component is within the range of from 20:1 to 1:1, preferably 18:1 to 2:1, more preferably 16:1 to 4:1, still more preferably 15:1 to 5:1, yet more preferably 14:1 to 6:1, even more preferably 13:1 to 7:1, most preferably 12:1 to 8:1, and in particular 11:1 to 9:1.

Preferably, the relative volume ratio of the first component to the second component is within the range of from 20:1 to 1:1, preferably 18:1 to 2:1, more preferably 16:1 to 3:1, still more preferably 15:1 to 3:1, yet more preferably 14:1 to 3:1, even more preferably 13:1 to 3:1, most preferably 12:1 to 8:1, and in particular 11:1 to 3:1.

A skilled person recognizes that other relative weight ratios can easily be realized and thus are also contemplated.

The curable adhesive according to the invention preferably provides gap filling of up to 100 mm without boiling, preferably at open times within the range of 12 to 16 minutes or even only 4 to 6 minutes. Gap filling is preferably determined in accordance with ASTM method D3931-93a.

The curable adhesive according to the invention preferably provides an elongation at break
of at least 30%, more preferably at least 40%, still more preferably at least 50%, yet more preferably at least 60%, even more preferably at least 70%, most preferably at least 80%, and in particular at least 90%, preferably in each case at a Young's modulus of at least 500 MPa; or
of at least 30%, more preferably at least 40%, still more preferably at least 50%, yet more preferably at least 60%, even more preferably at least 70%, most preferably at least 80%, and in particular at least 90%, preferably in each case at a Young's modulus of at least 600 MPa; or
of at least 30%, more preferably at least 40%, still more preferably at least 50%, yet more preferably at least 60%, even more preferably at least 70%, most preferably at least 80%, and in particular at least 90%, preferably in each case at a Young's modulus of at least 700 MPa.

Young's modulus and elongation at break are preferably determined in accordance with ASTM method D638.

The curable adhesive according to the invention preferably provides a very high T-peel strength without sacrificing lap shear strength, elongation at break or Young's modulus. Preferably, the curable adhesive according to the invention provides a T-peel strength of at least 8.0 N/mm, or at least 9.0 N/mm, or at least 10 N/mm, or at least 11 N/mm, more preferably at least 11.5 N/mm, still more preferably at least 12 N/mm, yet more preferably at least 12.5 N/mm, even more preferably at least 13 N/mm, most preferably at least 13.5 N/mm, and in particular at least 14 N/mm. The T-peel strength is preferably determined in accordance with ASTM method D1876-08(2015).

The curable adhesive according to the invention preferably provides a lap shear strength of at least 15 MPa, more preferably at least 16 MPa, still more preferably at least 17 MPa, yet more preferably at least 18 MPa, even more preferably at least 19 MPa, most preferably at least 20 MPa, and in particular at least 21 MPa. The lap shear strength is preferably determined in accordance with ASTM method D1002. The lap shear strength is preferably determined on aluminum substrates at a bond line thickness of 0.3 mm and upwards.

The curable adhesive according to the invention preferably exhibits a shrinkage determined using a rheometer or a pycnometer of not more than 18 vol.-%, more preferably not more than 17 vol.-%, still more preferably not more than 16 vol.-%, yet more preferably not more than 15 vol.-%, even more preferably not more than 14 vol.-%, most preferably not more than 13 vol.-% or not more than 12 vol.-%, and in particular not more than 10 vol.-%.

Conventional methods for the determination of shrinkage using a rheometer (e.g. TA Instruments AR/DHR and ARES-G2) or a pycnometer (e.g. Micromeritics AccuPyc® II 1340) are known to the skilled person.

Conventional methods for preparing two-component systems with a first component that is spatially separated from a second component in order to prevent premature reaction are known to the skilled person. Certain ingredients, such as the toughening agents and impact modifiers may be apportioned between the first component and the second component to provide for a similar viscosity of the first component and the second component. As indicated, the volume ratio and/or weight ratio between the first component and the second component can vary greatly, for example, from 15:1 to 1:1. In some embodiments, the ratio between the first component and the second component is 10:1 by volume or weight.

It should be noted that the order of addition in making the first component and the second component can vary greatly. Moreover, the commercial preparation of the first component and the second component may also involve making stock or premix solutions, cooling the formulations at intermediate and final steps, degassing the formulations under a vacuum, and the like. As appreciated by a skilled person, equipment that may be employed in making the first component and the second component include vessels, piping, valves, transfer pumps, vacuum pumps, mixers (e.g., high speed agitators or dispersers), and so forth. The first component and the second component may be delivered to the end-user in differing types of containers, ranging from small cartridges to drums, and the like.

After preparation of the first component and the second component of the curable adhesive according to the invention, the two components may be stored in inventory by the manufacturer, the distributor, end-user, and the like. The first component and the second component may alternatively be used or applied soon after transport (without intermediate storage) to bond substrates. However, it is common for either the manufacturer or the user to store the first component and the second component prior to combination and use of the two components. Thus, it is generally beneficial to have a consistent cure profile over the shelf life of the first component and the second component. Again, it is generally desirable for the user to know the behavior of the cure profile (e.g., peak exotherm temperature and time) to appropriately manage the application of the two-component system and the construction/bonding of the structural components, pieces, parts, and the like. Therefore, ingredients, such as cure profile regulators, cure accelerators, and stabilizers are added to the two-component system to provide for a more consistent cure profile. These ingredients may be added to the first component, to the second component, or to both.

To apply the adhesive, the first component and the second component are combined or mixed together, (e.g., through a static mixer). The combined first component and the second component may then be applied to a first substrate and/or a second substrate. After such application, the first substrate and the second substrate may be adhered to one another via the applied adhesive, i.e. via the combined first component and the second component. Lastly, the adhesive is allowed to cure, typically at ambient or room temperature (23° C.).

The open time (working time) is generally regarded as the time allowable between when the two-component system is mixed/applied to parts and parts must be mated. This amount of time is determined by the cure rate of the two-component system and is, therefore, also dependent on temperature and the mass of the two-component system. For the purpose of the specification, open time is the time span which may elapse after the first component and the second component have been mixed with one another and immediately thereafter have been applied to substrates, but before the substrates are mated, which still provides essentially equivalent bond strength after mating of substrates and complete curing of the adhesive. Open time is determined in a comparative experiment comparing bond strengths with one another. In the reference experiment, the first component and the second component are mixed with one another, immediately thereafter the mixture is applied to substrates, and immediately thereafter the substrates are mated. The adhesive is allowed to fully cure and the thus achieved bond strength is the reference bond strength. In a series of test experiments, the first component and the second component are mixed with one another, immediately thereafter the mixture is applied to substrates, but before the substrates are mated, in each case a predetermined time span elapses. After the substrates have been mated, the adhesive is again allowed to fully cure and the thus achieved bond strengths are the test bond strengths. When a given test bond strength is essentially equivalent compared to the reference bond strength, the corresponding elapsed time span is within the open time. When a given test bond strength is not essentially equivalent compared to the reference bond strength, the corresponding elapsed time span is outside the open time.

For the purpose of the specification, the open time is defined as the maximum time span that may elapse thereby still delivering essentially equivalent bond strength as the reference bond strength, i.e. as if the substrates were immediately mated upon initial application of the mixed two components. In this context “essentially equivalent” bond strength is commonly understood to be within 10% of the bond strength achieved with immediate mating of the substrates. Further, bond strength is commonly expressed in terms of lap shear strength reported as the failure stress in the adhesive, which is calculated by dividing the failing load by the bond area. Preferably, the lap shear strength is determined according to ASTM method D1002.

Preferably, open time is measured through the Delayed Mating Open Time (DMOT) test. In this test, adhesive is applied to a series of 2.54 cm (1″)×10.16 cm (4″) aluminum coupons as quickly as possible, then coupons are mated with a delay of successively longer intervals of time, with 1.27 cm (0.5″) overlap between the two coupons and a 254 μm (10 mil) bond line thickness. The adhesive is then allowed to cure completely (typically overnight), and the coupons are pulled apart in shear. The results of lap shear strength (LSS) and failure mode (adhesive vs. cohesive) are compared for each coupon to one mated with effectively zero delay, and the end of the open Time is then judged by a reduction in strength of >10% of the original and/or reduction in cohesive failure to <80% (>20% adhesive failure).

Preferably, the open time of the curable adhesive according to the invention is within the range of 3 to 15 minutes, preferably 4 to 14 minutes. In a preferred embodiment, the open time is within the range of 3 to 7 minutes, preferably 4 to 6 minutes. In another preferred embodiment, the open time is within the range of 11 to 15 minutes, preferably 12 to 14 minutes.

For the purpose of the specification, the time to handling strength (curing time, fixture time) is defined as the time required after the mixture of the first component and the second component has been applied and mated for the bond strength to exceed a value of 0.689 MPa (100 psi). A longer open time typically results in a longer time to handling strength. It is generally most desirable to have a time to handling strength that is minimally longer than the open time, sometimes referred to as “snap cure” or “cure on command”. Typically, final bond strength after curing is complete is much higher than 0.689 MPa (100 psi), typically greater than 10 MPa.

Preferably, time to handling strength is measured through the Rate of Bond Strength Development (ROBSD) test. In this test, adhesive is applied to a series of 2.54 cm (1″)×10.16 cm (4″) aluminum coupons which are then immediately mated to a second coupon with 1.27 cm (0.5″) overlap and a 254 μm (10 mil) bond line thickness. The coupons are then pulled apart in shear over successively longer intervals of time, evaluating the lap shear strength over time as the adhesive cures and bond strength increases. The time to handling strength is judged by the time that it takes for the bond strength to reach 0.689 MPa (100 psi).

Preferably, the time to handling strength of the curable adhesive according to the invention is within the range of 7 to 28 minutes, preferably 8 to 27 minutes. In a preferred embodiment, the time to handling strength is within the range of 7 to 11 minutes, preferably 8 to 10 minutes. In another preferred embodiment, the time to handling strength is within the range of 24 to 28 minutes, preferably 25 to 27 minutes.

Open time and time to handling strength can be purposefully adjusted by varying type and individual amount of adhesion promoter, accelerator, curative, stabilizer, and polymerization initiator. Thus, adjusting open time and time to handling strength can be achieved by routine experimentation. When the amount/concentration of adhesion promoter is increased, the open time and the time to handling strength are typically extended. When the amount/concentration of accelerator is increased, the time to handling strength is typically shortened. When the amount/concentration of curative is increased, the open time and the time to handling strength are shortened. When the amount/concentration of the stabilizer is increased, the open time and the time to handling are typically extended. The individual effect of the polymerization initiator depends upon the nature and amount of monomers to be polymerized.

Another aspect of the invention relates to a method for adhesively bonding a first substrate and a second substrate as described above, preferably a battery cooling plate or a cooling plate for an electronic component, via a cured adhesive thereby obtaining between the first substrate and the second substrate a conduit for a liquid coolant to flow through and to come into direct contact with the cured adhesive, the method comprising the steps of
(a) providing a curable adhesive as described above;
(b) applying the curable adhesive to the first substrate and/or the second substrate;
(c) optionally, allowing time to elapse prior to expiry of the open time, e.g. for performing some other action;
(d) adhering the first substrate and the second substrate to one another; and
(e) allowing the curable adhesive to cure thereby providing the cured adhesive.

Preferably, the curable adhesive is provided in form of a two-component system and step (a) comprises mixing the first component and the second component of the two-component system with one another.

Another aspect of the invention relates to an element as described above, preferably a battery cooling plate or a cooling plate for an electronic component, comprising a first substrate and a second substrate that are adhesively bonded via a cured adhesive thereby obtaining between the first substrate and the second substrate a conduit for a liquid coolant to flow through and to come into direct contact with the cured adhesive, wherein the cured adhesive is obtainable by curing a curable adhesive as described above.

The invention is further illustrated by the following examples which are not to be construed as limiting its scope.

### EXAMPLES 1 to 3

Adhesive 1 was a two-component acrylic adhesive containing the following acrylic monomers after mixing of the two components at the following weight content:

| Chemical Name | Content |
|---|---|
| Methyl methacrylate | 25-30% |
| Methacrylic acid | 1-5% |
| 2-Hydroxyethyl methacrylate | 5-15% |
| Isobornyl methacrylate | 1-5% |
| Zn dimethacrylate | 0.5-2% |
| Methacrylate phosphate ester | 1-5% |

Adhesive 2 was a commercial two-component acrylic adhesive. According to the product specification provided by the manufacturer, the acrylic adhesive after mixing of the two components contained the following acrylic monomers at the following weight content:

| Chemical Name | Range |
|---|---|
| Methyl methacrylate | 30-35% |
| Methacrylic acid | 1-5% |
| Methacrylate blend | 1-5% |
| Methacrylate phosphate ester | 1-5% |
| Methacrylate monomer | 0.1-0.9% |

Adhesive 3 was another commercial two-component acrylic adhesive. According to the product specification provided by the manufacturer, the acrylic adhesive after mixing of the two components contained the following acrylic monomers at the following weight content:

| Chemical Name | Range |
|---|---|
| Methyl methacrylate | 40-60% |
| Methacrylic acid | ≤10% |

Two aluminum substrates (Al 5754) each having a thickness of 2 mm and each pretreated by means of a laser were adhesively bonded to one another at a gap of 0.3 mm with the different curable two-component adhesives 1, 2 and 3. Curing of the adhesives was performed at room temperature (23° C.) for at least 4 days.

After immersing the test specimens to aqueous ethylene glycol for various duration at various temperatures, lap shear strength was measured at 23° C. according to ASTM method D1002. The immersion medium was 50/50 Glysantin® G40/water. In each case, three specimens were tested and the results are compiled in the table here below:

| | | | | | | lap shear | | | | | | |
|---|---|---|---|---|---|---|---|---|---|---|---|---|
| | | | | | | after aging | | | | relative lap shear | | |
| adhesive- | | | aging/immersion | | | [MPa] | failure mode % | | | per failure mode | | |
| sample | curing | | time | | temperature | (n = 3) | CF | SCF | AF | CF | SCF | AF |
| 1-1 | 4 | d | / | | / | 22.9 | 100 | 0 | 0 | 22.9 | 0 | 0 |
| 2-1 | | | | | | 18.7 | 67 | 33 | 0 | 12.5 | 6.2 | 0 |
| 3-1 | | | | | | 20.0 | 33 | 60 | 7 | 6.7 | 12.0 | 1.3 |
| 1-2 | 4 | d | 7 | d | 90° C. | 21.1 | 47 | 53 | 0 | 9.9 | 11.3 | 0 |
| 2-2 | | | | | | 21.5 | 0 | 93 | 7 | 0 | 20.1 | 1.4 |
| 3-2 | | | | | | 22.4 | 3 | 22 | 72 | 0.7 | 4.9 | 16.1 |
| 1-3 | 11 | d | 14 | d | 90° C. | 20.7 | 0 | 100 | 0 | 0 | 20.7 | 0 |
| 2-3 | | | | | | 17.6 | 43 | 57 | 0 | 7.6 | 10 | 0 |
| 3-3 | | | | | | 21.6 | 3 | 62 | 35 | 0.7 | 13.3 | 7.5 |

CF cohesive failure;
SCF semi-cohesive failure;
AF adhesive failure (EN ISO 10365)

The results are also illustrated in FIG. 3 where the measured value for lap shear strength in MPa has been split to partial contribution according to the observed failure mode, i.e. expressed as relative lap shear per failure mode.

When assessing performance based upon lap shear measurements, two aspects are especially relevant:
(i) lap shear failure value before and after aging/immersion in coolant liquid; and
(ii) failure mode, which is the most important parameter.

As adhesive failure is to be avoided, an adhesive providing a lower lap shear value at cohesive failure mode (CF) performs better than an adhesive providing a higher lap shear value at adhesive failure mode (AF).

As demonstrated by the above comparative experimental data, curable adhesives according to the invention provide resistance against aqueous ethylene glycol under various conditions, whereas the adhesive of Example 1 (1-1, 1-2, 1-3) performs better than the adhesive of Example 2 (2-1, 2-2, 2-3) which in turn performs better than the adhesive of Example 3 (3-1, 3-2, 3-3). It appears that a reduced content of C₁₋₆-alkyl (meth)acrylate such as methyl methacrylate and a significant content of hydroxy-C₁₋₆-alkyl (meth)acrylate such as 2-hydroxyethyl methacrylate and/or a significant content of cycloalkyl (meth)acrylate such as isobornyl methacrylate contribute to an improved resistance against aqueous ethylene glycol under the harsh testing conditions at 90° C.

### EXAMPLES 4 to 19

Adhesives 4 to 19 were based on adhesive 1. additionally containing fillers at the following weight content:

| | | | | | | | | |
|---|---|---|---|---|---|---|---|---|
| [wt.-%] | 4 | 5 | 6 | 7 | 8 | 9 | 10 | 11 |

Part A

| | | | | | | | | |
|---|---|---|---|---|---|---|---|---|
| first component of | 100.00 | 100.00 | 100.00 | 100.00 | 100.00 | 100.00 | 100.00 | 100.00 |
| adhesive 1 | | | | | | | | |
| aluminosilicate | 8.00 | — | — | 8.00 | — | — | — | — |
| micro-spheres | | | | | | | | |
| organophilic | 4.00 | 4.00 | 4.00 | 4.00 | 4.00 | 4.00 | — | — |
| phyllosilicate | | | | | | | | |
| muscovite mica | — | 4.00 | — | — | 4.00 | — | — | — |
| (phyllosilicate) | | | | | | | | |
| muscovite mica | — | 4.00 | — | — | 4.00 | — | — | — |
| (phyllosilicate) | | | | | | | | |
| mica (phyllosilicate) | — | — | — | — | — | — | — | — |
| kaolin clay | — | — | — | — | — | — | — | 8.00 |
| (phyllosilicate) | | | | | | | | |
| kaolin clay | — | — | — | — | — | — | — | — |
| (phyllosilicate) | | | | | | | | |
| precipitated aluminum | — | — | — | — | — | — | 8.00 | — |
| hydroxide | | | | | | | | |
| borosilicate glass | — | — | — | — | — | — | — | — |
| powder | | | | | | | | |
| cross-linked polymethyl | — | — | — | — | — | — | — | — |
| methacrylate | | | | | | | | |
| TOTAL | 112.00 | 112.00 | 104.00 | 112.00 | 112.00 | 104.00 | 108.00 | 108.00 |

Part B

| second component I | — | — | 25.00 | — | — | — | — | — |
|---|---|---|---|---|---|---|---|---|
| second component II | 28.00 | 28.00 | — | — | — | — | — | — |
| second component III | — | — | — | 10.00 | 10.00 | 10.00 | 10.00 | 10.00 |
| TOTAL | 28.00 | 28.00 | 25.00 | 10.00 | 10.00 | 10.00 | 10.00 | 10.00 |
| [wt.-%] | 12 | 13 | 14 | 15 | 16 | 17 | 18 | 19 |

Part A

| | | | | | | | | |
|---|---|---|---|---|---|---|---|---|
| first component | 100.00 | 100.00 | 100.00 | 100.00 | 100.00 | 100.00 | 100.00 | 100.00 |
| of adhesive 1 | | | | | | | | |
| aluminosilicate | — | — | 8.00 | — | — | — | — | — |
| micro-spheres | | | | | | | | |
| organophilic | — | — | — | — | — | — | — | — |
| phyllosilicate | | | | | | | | |
| muscovite mica | — | 4.00 | — | — | — | — | — | — |
| (phyllosilicate) | | | | | | | | |
| muscovite mica | — | 4.00 | — | — | — | — | — | — |
| (phyllosilicate) | | | | | | | | |
| mica | — | — | — | — | 8.00 | — | — | — |
| (phyllosilicate) | | | | | | | | |
| kaolin clay | — | — | — | — | — | — | — | — |
| (phyllosilicate) | | | | | | | | |
| kaolin clay | 8.00 | — | — | 4.00 | — | — | — | — |
| (phyllosilicate) | | | | | | | | |
| precipitated | — | — | — | — | — | — | — | — |
| aluminum hydroxide | | | | | | | | |
| borosilicate glass | — | — | — | — | — | 8.00 | — | — |
| powder | | | | | | | | |
| cross-linked polymethyl | — | — | — | — | — | — | 8.00 | — |
| methacrylate | | | | | | | | |
| TOTAL | 108.00 | 108.00 | 108.00 | 104.00 | 108.00 | 108.00 | 108.00 | 100.00 |

Part B

| | | | | | | | | |
|---|---|---|---|---|---|---|---|---|
| second component I | — | — | — | — | — | — | — | — |
| second component II | — | — | — | — | — | — | — | — |
| second component III | 10.00 | 10.00 | 10.00 | 10.00 | 10.00 | 10.00 | 10.00 | 10.00 |
| TOTAL | 10.00 | 10.00 | 10.00 | 10.00 | 10.00 | 10.00 | 10.00 | 10.00 |

Adhesive properties such as open time, elongation at break, tensile strength, young's modulus, and lap shear strength of two-component adhesives 4 to 19 were determined.

Two aluminum substrates (Al 5754) each having a thickness of 2 mm and each pretreated by means of abrasion and acetone cleaning were adhesively bonded to one another at a gap of 0.3 mm with the different curable two-component adhesives 4 to 19. Curing of the adhesives was performed at room temperature (23° C.) for at least 3 days. After immersing the test specimens to humid cataplasma in accordance with PSA D47 1165 for various duration at 70° C., lap shear strength was measured at 23° C. according to ASTM method D1002. The results are compiled in the table here below:

| | | time | | 4 | 5 | 6 | 7 | 8 | 9 | 10 | 11 | 12 |
|---|---|---|---|---|---|---|---|---|---|---|---|---|
| Lap | Lap shear [MPa] | / | | 16.6 | 16.1 | 15.5 | 15.7 | 16.9 | 18.7 | 17.2 | 16.4 | 17.9 |
| shear | Failure mode (% RC) | | | 100 | 100 | 100 | 100 | 100 | 100 | 100 | 100 | 100 |
| Alu | Lap shear [MPa] | 7 | d | 14.3 | 13.9 | 11.7 | 13.2 | 14.2 | 15.5 | 13.6 | 12.9 | 13.9 |
| 0.3 mm | Δ Lap shear [%] | | | −13.9 | −13.7 | −24.5 | −15.9 | −16.0 | −17.1 | −20.9 | −21.3 | −22.3 |
| | Failure mode (% RC) | | | 100 | 100 | 80 | 100 | 100 | 100 | 75 | 90 | 100 |
| | Lap shear [MPa] | 14 | d | 13.1 | 12.6 | — | 12.3 | 12.6 | 12.8 | 11.9 | — | — |
| | Δ Lap shear [%] | | | −21.1 | −21.7 | — | −21.7 | −25.4 | −31.6 | −30.8 | — | — |
| | Failure mode (% RC) | | | 100 | 100 | — | 100 | 100 | 70 | 50 | — | — |
| | Lap shear [MPa] | 21 | d | 12.1 | 12.3 | — | 11.9 | 11.4 | 12.5 | 11.4 | — | — |
| | Δ Lap shear [%] | | | −27.1 | −23.6 | — | −24.2 | −32.5 | −33.2 | −33.7 | — | — |
| | Failure mode (% RC) | | | 100 | 100 | — | 100 | 100 | 40 | 75 | — | — |

| | | | | | | | | | |
|---|---|---|---|---|---|---|---|---|---|
| Young's modulus E [MPa] | — | — | — | — | — | 736 | 768 | — | — |
| Tensile strength s [MPa] | — | — | — | — | — | 14 | 14.4 | — | — |
| Elongation at break [%] | — | — | — | — | — | 55 | 47 | — | — |
| Open time [min] | — | — | 3.5 | 4 | 4.5 | 5.5 | 4 | 3.5 | 4 |
| Exothermic time [min] (10 g) | — | — | 8 | 7 | 8 | 9 | 10 | 10 | 10 |
| Peak exotherm [° C.] | — | — | 80.8 | 112.9 | 113.2 | 114.5 | 112.5 | 101.1 | 91.9 |
| T.A. [° C.] | — | — | — | — | — | — | — | — | — |

| | | time | | 13 | 14 | 15 | 16 | 17 | 18 | 19 |
|---|---|---|---|---|---|---|---|---|---|---|
| Lap | Lap shear [MPa] | / | | 16.2 | 15.4 | 19.6 | 14 | 16.1 | 18.4 | 21 |
| shear | Failure mode (% RC) | | | 100 | 100 | 100 | 100 | 100 | 100 | 100 |
| Alu | Lap shear [MPa] | 7 | d | 11.9 | 11.2 | 13.8 | 9.35 | — | — | 13.8 |
| 0.3 mm | Δ Lap shear [%] | | | −26.5 | −27.3 | −29.6 | −33.2 | — | — | −34.3 |
| | Failure mode (% RC) | | | 100 | 100 | 90 | 100 | — | — | 100 |
| | Lap shear [MPa] | 14 | d | 10.9 | — | — | — | 11.5 | 11.4 | — |
| | Δ Lap shear [%] | | | −32.7 | — | — | — | −28.6 | −38.0 | — |
| | Failure mode (% RC) | | | 100 | — | — | — | 40 | 30 | — |
| | Lap shear [MPa] | 21 | d | 9.45 | — | — | — | — | — | — |
| | Δ Lap shear [%] | | | −41.7 | — | — | — | — | — | — |
| | Failure mode (% RC) | | | 100 | — | — | — | — | — | — |

| | | | | | | | |
|---|---|---|---|---|---|---|---|
| Young's modulus E [MPa] | — | — | — | — | 766 | 775 | — |
| Tensile strength s [MPa] | — | — | — | — | 13.5 | 16 | — |
| Elongation at break [%] | — | — | — | — | 55 | 70 | — |
| Open time [min] | 4.5 | 5 | 5 | 4.5 | 5 | 5 | 4.5 |
| Exothermic time [min] (10 g) | 10 | 10 | 11 | 10 | 13 | 11 | 10.5 |
| Peak exotherm [° C.] | 112 | 108.8 | 103.2 | 102.2 | 106.1 | 107.3 | 118.5 |
| T.A. [° C.] | — | 21.7 | 19.4 | — | 18.5 | 19.3 | — |

For humid cataplasma, the samples were covered by cotton than placed in a bag. The same weight of water and cotton was added than the bag was sealed and put it in an oven at 70° C. for various duration. After this step, the samples were placed for 2 hours at −20°° C. than kept at room temperature (23° C.) to warm and reach the room temperature. The samples were tested in an interval of 2 to 4 hours.

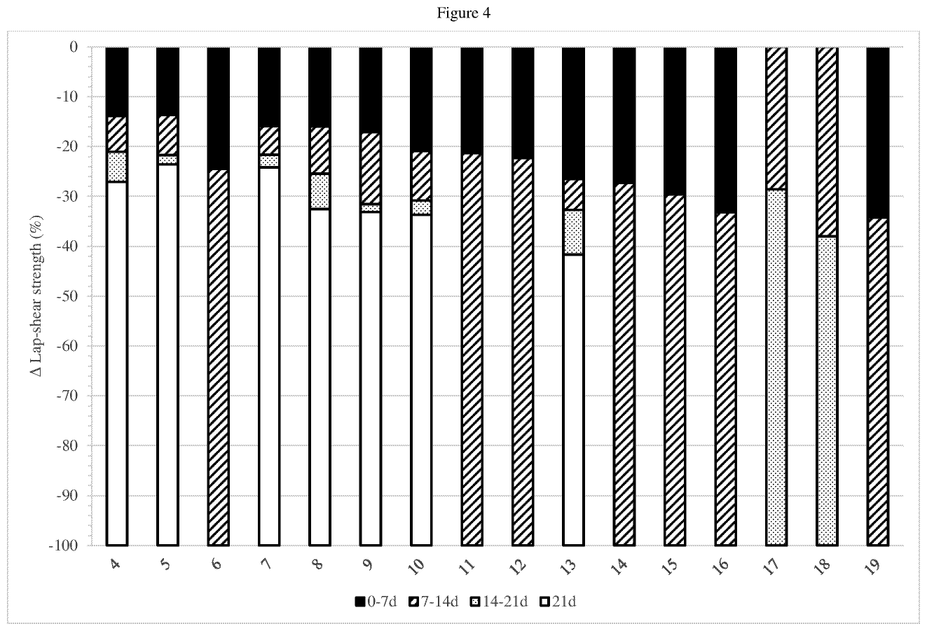

The results of lap shear strength are also illustrated in FIG. 4 where the lap shear strength in percent has been split to partial contribution according to the relative decrease of lap shear strength, i.e. expressed as relative loss of lap shear per time interval.

As demonstrated by the above comparative experimental data, curable adhesives according to the invention achieve excellent adhesive properties, whereas the adhesive of Example 7 performs better than the adhesive of Example 19. It appears that a significant content of filler such as silicates, in particular a combination of at least two silicates, e.g. aluminosilicate and organophilic phyllosilicate, contributes to an improved resistance against humid aging under the harsh testing conditions at 70° C.

Two aluminum substrates (Al 5754) each having a thickness of 2 mm and each pretreated by means of abrasion and acetone cleaning were adhesively bonded to one another at a gap of 0.3 mm with the different curable two-component adhesives 19 and 7. Curing of the adhesives was performed at room temperature (23°° C.) for 3 days.

After immersing the test specimens to aqueous ethylene glycol for various duration at various temperatures, lap shear strength was measured at 23° C. according to ASTM method D1002. The immersion medium was 50/50 Glysantin® G40/water. In each case, three specimens were tested and the results are compiled in the table here below:

| | | | | | lap shear | | | | |
|---|---|---|---|---|---|---|---|---|---|
| | | | | | after aging | | | relative lap shear | |
| | | aging/immersion | | | [MPa] | failure mode % | | per failure mode | |
| adhesive | curing | time | | temperature | (n = 3) | CF | AF | CF | AF |
| 19-1 | 3 d | / | | / | 24.0 | 100 | 0 | 24.0 | 0 |
| 7-1 | | | | | 17.0 | 100 | 0 | 17.0 | 0 |
| 19-2 | 3 d | 7 | d | 90° C. | 16.2 | 48 | 52 | 7.8 | 8.4 |
| 7-2 | | | | | 14.7 | 100 | 0 | 14.7 | 0 |
| 19-3 | 3 d | 14 | d | 90° C. | 14.1 | 30 | 70 | 4.2 | 9.9 |
| 7-3 | | | | | 14.1 | 93 | 7 | 13.2 | 0.9 |

CF cohesive failure;
AF adhesive failure (EN ISO 10365)

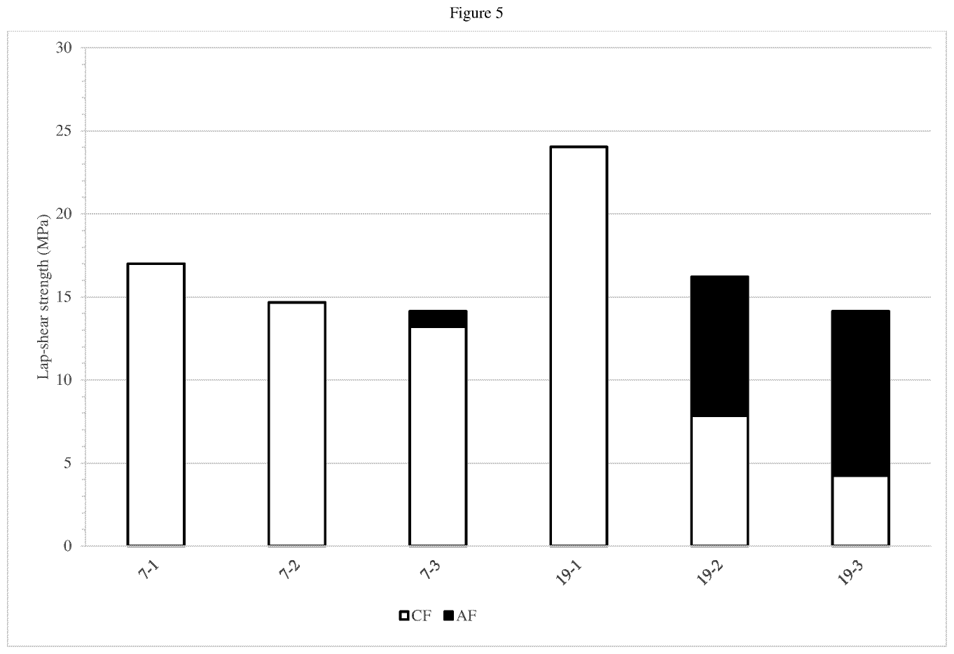

The results are also illustrated in FIG. 5 where the measured value for lap shear strength in MPa has been split to partial contribution according to the observed failure mode, i.e. expressed as relative lap shear per failure mode.

As demonstrated by the above comparative experimental data, curable adhesives according to the invention provide resistance against aqueous ethylene glycol under various conditions, whereas the adhesive of Example 7 (7-1, 7-2, 7-3) performs better than the adhesive of Example 19 (19-1, 19-2, 19-3). It appears that a significant content of filler such as silicates, in particular a combination of at least two silicates, e.g. aluminosilicate and organophilic phyllosilicate, contributes to an improved resistance against aqueous ethylene glycol under the harsh testing conditions at 90° C.

1-29. (canceled)

30. The method according to claim 96, wherein the curable adhesive includes one or more additional ethylenically unsaturated monomers and the one or more additional ethylenically unsaturated monomers comprise a glycolether (meth)acrylate according to general formula (I),
CH₂═CR—C(═O)—O—[CH₂CH₂—O]ₙ-CₘH₂ₘ₊₁ (I),
wherein R is —H or —CH₃;
index n is an integer within the range of from 1 to 12; and
index m is an integer within the range of from 1 to 8.

31. The method according to claim 30, wherein in the glycolether (meth)acrylate according to general formula (I) is selected from the group consisting of methylmonoglycol (meth)acrylate, ethylmonoglycol (meth)acrylate, propylmonoglycol (meth)acrylate, butylmonoglycol (meth)acrylate, methyldiglycol (meth)acrylate, ethyldiglycol (meth)acrylate, propyldiglycol (meth)acrylate, butyldiglycol (meth)acrylate, methyltriglycol (meth)acrylate, ethyltriglycol (meth)acrylate, propyltriglycol (meth)acrylate, and butyltriglycol (meth)acrylate; preferably butyldiglycol methacrylate; preferably butyldiglycol methacrylate.

32. The method according to claim 30, wherein the content of the glycolether (meth)acrylate according to general formula (I) is within the range of 10±8.0 wt.-%, preferably 10±6.0 wt.-%, relative to the total weight of the curable adhesive.

33. The method according to claim 30, wherein the relative weight ratio of the C₁₋₆-alkyl (meth)acrylate to the glycolether (meth)acrylate is with-in the range of (10±9):1, more preferably (10±8):1, still more preferably (10±7):1, yet more preferably (10±6):1, even more preferably (10±5):1, most preferably (10±4):1, and in particular (10±3):1.

34. The method according to claim 30, wherein the curable adhesive comprises a (meth)acrylic acid being methacrylic acid, a C₁₋₆-alkyl (meth)acrylate being methyl methacrylate, and a hydroxy-C₁₋₆-alkyl (meth)acrylate being hydroxyethyl methacrylate.

35. The method according to claim 34, wherein the curable adhesive additionally comprises a cycloalkyl (meth)acrylate being isobornyl methacrylate.

36. The method according to claim 35, wherein the curable adhesive additionally comprises a glycolether (meth)acrylate according to general formula (I) being butyldiglycol methacrylate.

37. The method according to claim 96, wherein the polymerization initiator is a peroxide polymerization initiator.

38. The method according to claim 96, wherein the polymerization initiator is selected from the group consisting of benzoyl peroxide, tertbutyl hydroperoxide, di-tertbutyl peroxide, cumene hydroperoxide, dicumene peroxide, tertbutyl peracetate, tertbutyl perbenzoate, and di-tertbutyl perphthalate; preferably benzoyl peroxide.

39. The method according to claim 30, wherein the curable adhesive additionally comprises a first toughening agent.

40. The method according to claim 39, wherein the first toughening agent is a liquid toughening agent; preferably a (meth)acrylate terminated butadiene-acrylonitrile copolymer.

41. The method according to claim 39, wherein the content of the first toughening agent is within the range of 8.0±6.0 wt .-%, preferably 8.0±4.0 wt.-%, more preferably 8.0±2.0 wt.-%, relative to the total weight of the curable adhesive.

42-44. (canceled)

45. The method according to claim 96, wherein the curable adhesive essentially does not contain any copolymer or block-copolymer selected from the group consisting of styrene-butadiene rubber (SBR) other than SBS, styrene-ethylene-butadiene-styrene (SEBS), styrene-isoprene-styrene (SIS), acrylonitrile butadiene styrene copolymers (ABS), acrylonitrile styrene acrylate copolymers (ASA), acrylonitrile-ethylene-propylene-diene-styrene (AES), styrene acrylonitrile (SAN), methyl methacrylate-butadiene-styrene (MBS), and styrene-acrylonitrile (SAN).

46-57. (canceled)

58. The method according to claim 30, wherein the curable adhesive additionally comprises a curative; preferably a curative selected from N,N-dimethyl-para-toluidine (DMPT), N-(2-hydroxyethyl)-N-methyl-para-toluidine (MHPT), N-methyl-N-(2-hydroxypropyl)-p-toluidine (2HPMT), and N-ethyl-N-(2-hydroxyethyl)-p-toluidine (EHPT).

59. The method according to claim 58, wherein the content of the curative is within the range of 1.0±0.8 wt.-%, preferably within the range of 1.0±0.5 wt.-%, relative to the total weight of the curable adhesive.

60. The method according to claim 58, wherein the curable adhesive additionally comprises a cure indicator; preferably leucocrystal violet.

61. The method according to claim 60, wherein the content of the cure indicator is at most 0.1 wt.-%, relative to the total weight of the curable adhesive; preferably at most 0.09 wt.-%, at most 0.08 wt.-%, at most 0.07 wt.-%, at most 0.06 wt.-%, or at most 0.05 wt.-%.

62. The method according to claim 60, wherein the cure indicator is contained at a concentration that is so low that the cure indicator as such has no influence of the progress of the polymerization and curing reaction.

63-79. (canceled)

80. The method according to claim 96, wherein the curable adhesive includes a filler comprising particles having an average particle size of
at least 1.0 μm, preferably at least 1.5 μm, more preferably at least 2.0 μm, still more preferably at least 2.5 μm, yet more preferably at least 3.0 μm, even more preferably at least 3.5 μm, most preferably at least 4.0 μm, and in particular at least 4.5 μm;
at most 22.5 μm, preferably at most 20 μm, more preferably at most 17.5 μm, still more preferably at most 15 μm, yet more preferably at most 12.5 μm, even more preferably at most 10 μm, most preferably at most 7.5 μm, and in particular at most 5.0 μm; and/or
within the range of 5.0±4.8 μm, preferably 5.0±2.4 μm;
in each case determined by centrifugal liquid sedimentation according to ISO 13318.

81-95.(canceled)

96. A method for adhesively bonding a first substrate and a second substrate via a cured adhesive thereby obtaining between the first substrate and the second substrate a conduit for a liquid coolant to flow through and to come into direct contact with the cured adhesive, the method comprising the steps of
(a) providing a curable adhesive comprising:
(i) a (meth)acrylic acid;
(ii) a C₁₋₆-alkyl (meth)acrylate;
(iii) optionally, a hydroxy-C₁₋₆-alkyl (meth)acrylate;
(iv) optionally, a cycloalkyl (meth)acrylate;
(v) optionally, one or more additional ethylenically unsaturated monomers; and
(vi) a polymerization initiator;
(b) applying the curable adhesive to the first substrate and/or the second substrate;
(c) optionally, allowing time to elapse prior to expiry of the open time, e.g. for performing some other action;
(d) adhering the first substrate and the second substrate to one another; and
(e) allowing the curable adhesive to cure thereby providing the cured adhesive.

97. The method according to claim 96, wherein the first substrate and the second substrate form a battery cooling plate or a cooling plate for an electronic component.

98-99. (canceled)
